(19) United States
(12) Patent Application Publication
(10) Pub. No.: US 2006/0023898 A1
(43) Pub. Date: Feb. 2, 2006

(54) Apparatus and method for producing sound

(76) Inventor: Shelley Katz, Cambridge (GB)

Correspondence Address: Lance J. Lieberman, Suite 1210, 551 Fifth Avenue, New York, NY, 10176, US

(21) Appl. No.: 11/188,164

(22) Filed: Jul. 22, 2005

Related U.S. Application Data
(63) Continuation-in-part of application No. 10/178,149, filed on Jun. 24, 2002.
(63) Continuation-in-part of application No. PCT/GB03/00324, filed on Jan. 22, 2003.

(51) Int. Cl. H03G 5/00

(52) U.S. Cl. 381/98; 381/99

(57) ABSTRACT

A sound reproduction method and apparatus utilizes both distributed mode and pistonic loudspeakers which are simultaneously driven over frequency ranges which at least partially overlap, for enhancing the spaciousness of the sound produced. The disclosure includes monophonic, stereophonic and multi-channel sound reproduction systems and electronic musical instruments such as digital pianos.

### CROSS-REFERENCE TO RELATED APPLICATIONS

This application is a continuation-in-part of U.S. patent application Ser. No. 10/178,149, filed Jun. 24, 2002. This application is also a continuation-in-part of International Application No. PCT/GB2003/000324, filed Jan. 22, 2003.

### FIELD OF THE INVENTION

This invention relates to an apparatus and method for producing sound and includes a novel loudspeaker assembly and novel electronic circuitry for driving the loudspeaker assembly. The invention is applicable particularly to reproduction of recorded or broadcast sound and to the production of sound from electronic musical instruments, especially digital pianos.

### BACKGROUND OF THE INVENTION

For decades, the production and reproduction of sound electrically has been the subject of constant research and development. One aspect of the research concerns the performance of loudspeakers with a view to improving the fidelity and quality of the sound they produce, for example with a view to producing a loudspeaker whose moving elements will faithfully follow the variations in the electrical signal driving them. Another aspect of the research and development concerns techniques for encoding, recording, broadcasting and decoding electrical signals representing sound with a view to improving the realism of the sounds as reproduced by loudspeakers driven by the decoded signals.

Fidelity and Loudspeaker Design

As a result of the search for improvement in loudspeakers, there are currently available a number of different types of loudspeaker operating on respective different principles.

For example, there is the conventional cone loudspeaker in which a compliantly mounted cone of relatively rigid material is driven electromagnetically by means of a moving coil or a moving magnet. This type of loudspeaker has probably achieved widest popularity and is used in a wide variety of different applications, each having its own specific design requirements. Examples of applications are in home entertainment systems for reproducing music, speech or audio-visual material, public address systems, audio outputs of computers, cinema and theatre sound systems, in-car entertainment, public address systems and electrical or electronic musical instruments, such as digital pianos.

No cone loudspeaker has yet been devised which can generate sound with good fidelity across the whole range of audio frequencies, specifically from 50 Hz or less to about 20 kHz. Hence good-quality sound, for example for faithful music reproduction, can only be achieved with cone loudspeakers when two or more units, each designed for a particular frequency band, are used in combination. The driving signal to these units is accordingly passed through circuits, known as crossover circuits, which direct the different frequency bands of the driving signal to the appropriate cone loudspeaker. Many good quality speaker systems typically employ at least three cone loudspeakers, one for the high frequencies, this being known as a tweeter, one for the mid-range and the third for the low frequencies, known as a woofer or a sub-woofer. Modern cone loudspeaker systems can reproduce sound with a relatively flat frequency response over substantially the whole of the frequency range audible to human beings with relatively high fidelity, and are currently by far the most widely used type of loudspeaker for the reproduction of music.

Another type of loudspeaker which is in use is the electrostatic loudspeaker in which a light stretched plastic membrane is caused to vibrate by an alternating electrostatic field produced from the driving signal by a pair of electrodes between which the membrane is positioned. Because the membrane is particularly light and therefore has low mechanical inertia, the motion of the membrane can reproduce the applied signal even at high frequencies with relatively high fidelity. A particular characteristic of electrostatic loudspeakers is the high degree of clarity of sound which they produce compared to other forms of loudspeaker. However, electrostatic loudspeakers as currently available commercially cannot produce the lowest frequencies which arise in music. Despite this, and despite the fact that electrostatic loudspeakers produce lower sound pressure levels than can be produced by cone loudspeakers, many consider that electrostatic loudspeakers do provide particularly high fidelity over the frequency range at which they can operate.

The above described cone loudspeakers and electrostatic loudspeakers generate sound by pistonic motion of the cone or membrane.

A third type of loudspeaker, which does not rely upon pistonic motion, has come into use in recent years. This is known as a distributed mode loudspeaker.

These are described in numerous publications, for example:
(a) PCT application WO 97/09842
(b) U.S. Pat. No. 6,399,870
(c) An article entitled “NXT Up Against the Wall” by Henry Azima which appeared in the September 1998 edition of the journal “Audio” published by Hachette Filipacchi Magazines Inc.
(d) A paper entitled The Distributed Mode Loudspeaker (DML) as a Broad-Band Acoustic Radiator by Neil Harris and Malcolm Omar Hawksford presented at the 103rd Audio Engineering Society Convention 1997 Sep. 26-29 New York.
(e) A paper entitled Boundary Interaction of Diffuse Field Distributed Mode Radiators by Henry Azima and Neil Harris presented at the 103rd Audio Engineering Society Convention 1997 Sep. 26-29 New York.
(f) A paper entitled Distributed Mode Loudspeaker Simulation Model by Joerg W. Panzer and Neil Harris presented at the 104th Audio Engineering Society Convention 1998 May 16-19 Amsterdam.
(g) A paper entitled Distributed Mode Loudspeaker Radiation Simulation by Joerg Panzer and Neil Harris presented at the 105th Audio Engineering Society Convention 1998 Sep. 26-29 San Francisco, Calif.

The contents of these publications are incorporated herein by reference. The structure and operation of such distributed mode loudspeakers has also been described in numerous other published papers, some of which are referenced in the above referred to articles and papers.

As is described in the above publications, a distributed mode loudspeaker comprises a panel and one or more transducers which are attached to the panel and, when activated by an electrical audio signal, generate resonant bending waves in the panel, which waves are distributed in a complex pattern over the surface, or the required part of the surface, of the panel. The excitation of the panel into these distributed resonant modes by the transducer requires that the panel be constructed so that it is capable of being excited into these resonant modes and that the transducer or transducers be carefully positioned having regard to the characteristics of the panel so that the required resonant modes are produced in the panel. Those skilled in the art of distributed mode loudspeakers are able to design such loudspeakers in a variety of sizes and using a variety of different materials and different forms of transducer.

The successful design of a distributed mode loudspeaker is a complex operation since the manner in which the panel vibrates and the frequency response is dependent upon a large number of different parameters including the panel width, height, thickness, material, the density of the material, the Poisson ratio, the bending rigidity, the damping factor, the shear ratio, the shear modulus, the nature and positioning of the transducers and the number of transducers employed. In practice, it is necessary to compute the frequency response from mathematical equations, in which connection, reference is made to the above identified publications relating to distributed mode loudspeakers. A computer program for performing these calculations and thereby facilitating the successful design of distributed mode loudspeakers is commercially available from New Transducers Limited, Signet House, Kingfisher Way, Hinchingbrook Business Park, Huntingdon postcode PE29 6FW. This computer program allows the designer to enter or select the various relevant parameters of the proposed loudspeaker and the computer program computes the resulting frequency response and vibration characteristics of the proposed loudspeaker to allow the designer to make appropriate design decisions.

Apart from the above computer program, distributed mode loudspeakers are commercially available from a number of different sources, for example, Amina Technologies Ltd, Cirrus House, Glebe Road, Huntingdon, Cambridgeshire PE29 7DX, England; Tannoy Limited, Coatbridge ML5 4TF, Scotland; Mission (UK) Ltd, Stonehill, Huntingdon, Cambridgeshire PE29 6EY, England; or Armstrong World Industries, 2500 Columbia Avenue, Lancaster, Pa. 17603, USA.

Various proposals have been made for the deployment of distributed mode loudspeakers in combination with other forms of loudspeaker. For example, because currently available distributed mode loudspeakers are not capable of reproducing faithfully frequencies below about 100 Hz, it has been proposed to use them with a sub-woofer which is separate from the distributed mode loudspeaker, the two loudspeakers being driven via appropriate filtering (crossover) circuits. Also, loudspeaker assemblies are commercially available in which there is provided in combination, in a common casing, a distributed mode loudspeaker used as a tweeter, one or more conventional cone loudspeakers acting as a woofer and/or mid-range loudspeakers, and conventional crossover circuits so that the distributed mode loudspeaker is driven exclusively by frequencies in the band appropriate to tweeters and the cone loudspeaker or cone loudspeakers is or are driven exclusively by frequencies in the bands appropriate to woofers and mid-range loudspeakers.

Another proposal for a full frequency range loudspeaker system utilising a distributed mode loudspeaker is described in U.S. Pat. No. 6,351,542 (Azima et al). In this patent, a distributed mode loudspeaker forms one wall of a closed chamber which is connected through a pipe to an enclosure containing a low frequency loudspeaker (woofer) so that the air pressure variations generated in the enclosure containing the woofer are transmitted through the pipe to the closed chamber. The distributed mode loudspeaker is supported at its edges by compliant material so that it may move pistonically in response to the air pressure variations in the closed chamber and thereby produce low frequency sound, effectively by pistonically vibrating in sympathy with the woofer.

Published PCT application WO 97/09842, already referred to above, itself discloses a large number of potential applications and arrangements for distributed mode loudspeakers. One arrangement disclosed in this PCT application proposes utilising curved panels in distributed mode loudspeakers with a view to focussing the sound in a particular direction. Another arrangement (FIG. 65 of the PCT application) proposes forming at least one wall of the casing of a conventional loudspeaker as a passive panel which is capable of resonant mode vibration but is caused to vibrate not through an electromagnetic transducer but by sympathetic vibrations induced by the air pressure variations arising within the loudspeaker enclosure when the conventional cone loudspeakers, which include a woofer, a mid-range and a tweeter, are driven. This arrangement is said to enable desirable colouration to be achieved.

An important advantage of distributed mode loudspeakers is that they can be made with a relatively flat profile, enabling them to be used in situations where a cone loudspeaker would be inconvenient or visually intrusive. However, distributed mode loudspeakers have not yet achieved wide use in the field of high fidelity music reproduction, possibly because, although they can be made to produce sounds over a large part of the frequency range audible to human beings, their frequency response is not yet as flat as can be achieved with well designed cone loudspeakers.

Realism and Sound Encoding Techniques

The research into improvement in the realism of reproduced sound resulted in the development of stereophonic systems in which a recording or broadcast includes distinct signals, provided in separate channels, for driving loudspeakers positioned in front of the listener to his left and to his right. These systems came into wide commercial use in the 1950s and 1960s and continue in use. They make it possible to create an impression, for the listener, of sounds being produced at different locations in front of him and of sounds moving across the sound Astage@. They also provide an impression of the spaciousness and full sound produced by, for example, a symphony orchestra or musical instrument such as a piano, which is superior to that given by reproducing sound using a single signal channel.

with a view to further improving the impression of spaciousness, and providing for the possibility of special effects such as the apparent movement of the sound source through a three dimensional space in which a listener is located, four channel systems, known as quadraphonic systems, were developed in the 1960s. Although some recordings and some broadcasts were made at the time, quadraphonic systems did not then come into wide use. One of the problems with the systems is that they required special recording and broadcast techniques in which different signals were encoded in different channels and four loudspeakers positioned, in essence, at the four corners of the listening room, with the listener located in the central area of the space between the four loudspeakers. Although these systems did not at the time come into wide use, they were able to produce an improvement, relative to stereophonic systems, both in the impression of spaciousness i.e. the impression that the listener is listening to the sound in a room substantially larger than the room he is actually listening in, and in Aenvelopment@ i.e. generating a feeling in the listener that he is enveloped by the sound. Together, these impressions give the listener a psycho-acoustic experience which more closely resembles the experience which he would have in listening to music in a concert hall whose acoustics are such as to provide appropriate levels of reflection of sounds from the walls and appropriate reverberation times.

In recent years so called Asurround sound@ systems have come into use, particularly in the cinema and in so-called Ahome cinema@ entertainment systems. One of the main purposes of the surround sound system is the production of special acoustic effects, such as the simulation of the sound of a vehicle passing through the space containing the surround sound system and the listeners. Typically, surround sound systems comprise five channels, respectively for driving left and right loudspeakers in front of the listener, left and right loudspeakers at the sides of the listener and a front centre loudspeaker. The systems require the signal to be reproduced to be encoded individually in each of five different channels so that each separate loudspeaker can be individually driven by its own dedicated signal, as encoded in the recording or broadcast signal. With appropriate signal encoding, the surround systems can provide an improvement in the spaciousness and envelopment of the sound compared to stereophonic systems.

### SUMMARY OF THE INVENTION

Despite the extensive improvements which have been achieved over past decades in loudspeaker design and signal encoding as discussed, there remains a need for a system which can produce enhanced sounds from electrical signals at reasonable cost and particularly a system in which the spaciousness of the sound is improved.

In one aspect, the present invention achieves an improvement in spaciousness and/or envelopment, by simultaneously driving at least one pistonic loudspeaker and at least one distributed mode loudspeaker in which the frequency ranges over which the loudspeakers operate overlap in at least part of the frequency range audible by human beings. It is preferable that the overlapping part of the frequency range should at least include relatively low frequencies.

It has been surprisingly found that, by reproducing sound in this way, enhanced spaciousness and/or envelopment can be achieved, even in single channel (mono) systems. Hence, the invention is applicable to single channel, stereophonic and multi-channel sound reproduction systems.

The enhancements in spaciousness, and also enhancements in envelopment and warmth of the sound will be further discussed below by reference to comparative experiments which have been conducted, and the results of which are represented in FIGS. 1 to 7 of the accompanying drawings. Practical embodiments of the invention will be described with reference to FIGS. 8 to 31 of the accompanying drawings.

### BRIEF DESCRIPTION OF THE DRAWINGS

In the accompanying drawings:

FIG. 1 is a bar chart showing the Lateral Early Energy Fraction (LEF) measured in a first experiment using a stereophonic sound reproduction system, comparing the LEFs obtained using conventional cone loudspeakers alone, distributed mode loudspeakers alone and a combination of both in accordance with an embodiment of the invention;

FIG. 2 is a bar chart showing Inter-Aural Cross-Correlation Coefficient (IACC) measured in the experiment referred to in connection with FIG. 1;

FIGS. 3 and 4 are bar charts similar to FIGS. 1 and 2 but showing the LEFs and IACCs obtained in a second experiment in which a mono sound reproduction system is used;

FIGS. 5 and 6 show respectively the frequency responses of a conventional cone loudspeaker and a distributed mode loudspeaker used in a third experiment in relation to the invention;

FIG. 7 shows the frequency responses obtained when the loudspeakers to which FIGS. 5 and 6 relate are driven simultaneously, with the respective different curves of FIG. 7 showing the results obtained when the relative sound pressure levels of the two loudspeakers are varied;

FIG. 8 is a block diagram of a stereophonic sound reproduction apparatus according to a first embodiment of the invention;

FIG. 9 is a diagrammatic perspective view of a loudspeaker assembly, included in the apparatus of FIG. 8;

FIG. 10 shows in diagrammatic section view a part of a distributed mode loudspeaker included in the assembly of FIG. 9, showing an electromagnetic actuator attached to the loudspeaker panel;

FIG. 11 is a diagrammatic perspective view of a section of the distributed mode loudspeaker of the assembly of FIG. 9, showing the mounting of the loudspeaker panel in a supporting frame;

FIG. 12 is a diagrammatic side sectional view will you of the loudspeaker assembly of FIG. 9, showing a diagrammatic block circuit diagram for the assembly;

FIG. 13 is a block diagram of a stereophonic sound reproduction apparatus according to a second embodiment of the invention;

FIG. 14 is an electrical block diagram of a signal adjusting circuit included in the apparatus of FIG. 13 for driving the distributed mode loudspeakers included therein;

FIG. 15 is an electrical block diagram showing a modification of the circuit of FIG. 14, FIG. 15 thus constituting a partial electrical block diagram of a third embodiment of the invention;

FIG. 16 is a block diagram of a stereophonic sound reproduction apparatus according to a fourth embodiment of the invention;

FIG. 17 is a block diagram of a stereophonic sound reproduction apparatus according to a fifth embodiment of the invention;

FIG. 18 is a block diagram of a stereophonic sound reproduction apparatus according to a sixth embodiment of the invention;

FIG. 19 is an electrical block diagram of a stereophonic amplifier included in the apparatus of FIG. 18;

FIG. 20 is a block diagram of a stereophonic sound reproduction system according to a seventh embodiment of the invention;

FIG. 21 is a block diagram of a stereophonic sound reproduction system according to an eighth embodiment of the invention;

FIG. 22 is a diagrammatic perspective view of a stereophonic sound reproduction apparatus according to a ninth embodiment of the invention;

FIG. 23 is a diagrammatic circuit diagram of part of the apparatus shown in FIG. 22;

FIG. 24 is a block diagram of a stereophonic sound reproduction system according to a tenth embodiment of the invention;

FIG. 25 is a block diagram of a “surround sound” sound reproduction system according to an eleventh embodiment of the invention;

FIG. 26 is a perspective view of a digital grand piano in accordance with an embodiment of the present invention;

FIG. 27 is a schematic block diagram of the digital piano of FIG. 26;

FIG. 28 is a rear perspective view of a digital upright piano according to an embodiment of the invention;

FIG. 29 is a block diagram of the digital piano of FIG. 28;

FIG. 30 is a block diagram of further embodiment of a digital piano in accordance with the invention; and

FIG. 31 is a block diagram of an add-on unit, according to a further embodiment of the invention, shown connected to a conventional digital piano so that the add-on unit and the conventional digital piano in combination implement the invention.

### DETAILED DESCRIPTION OF THE PRESENTLY PREFERRED EMBODIMENTS

The invention will now be described with reference to a series of experiments and to various currently-preferred embodiments. The entire content of co-pending U.S. patent application Ser. No. 10/178,149, filed Jun. 24, 2002 and entitled Electronic Piano, is expressly incorporated by reference herein. The entire content of International Application No. PCT/GB2003/000324, filed Jan. 22, 2003 and entitled Apparatus and Method for Producing Sound, is also expressly incorporated by reference herein.

### Experiments

General Introduction to Experiments

In order to investigate the surprising increase in the impression of spaciousness achieved by combining distributed mode and pistonic loudspeakers in accordance with the invention, a number of experiments have been conducted in a number of different environments and utilising, in the different environments, different loudspeakers and other equipment.

All of the experiments involved the use of top quality studio monitor cone loudspeaker systems and top quality distributed mode loudspeakers. Each experiment included subjective listening tests performed on expert listeners, different listeners present in the different experiments.

One experiment (the first to be described in detail below) employed a stereophonic system located in a professional listening room designed to emulate acoustically typical listening conditions encountered in a living room in a home. The listening room was roughly equivalent to the size of a large living room with randomly distributed reflective and non-reflective surfaces around the walls and with carpet on the floor and with some items of highly absorbent furniture. The acoustic was relatively Adead@ as in a living room containing soft furnishings and curtains.

The second experiment was conducted using mono equipment in a different professional listening room half the size of that used in the first mentioned experiment above and having walls which absorb frequencies above 10,000 Hz. Like the first room, the acoustic was relatively Adead@. Mono equipment was used.

Mono equipment was also used in the third experiment to be described. The loudspeakers were positioned in a particularly unfavourable acoustic at the intersection of two corridors each about 2 metres wide and extending at right angles to each other. Listening tests were conducted with the subjects in one of the corridors about 3 metres from the loudspeakers with the loudspeakers oriented to face into the corridor in which the listeners were located.

In all experiments, the subjective listening tests disclosed a perceived improvement in spaciousness when the distributed mode and cone loudspeakers were driven simultaneously as compared to when the cone loudspeakers were driven alone or the distributed mode loudspeakers were driven alone. In order to determine whether or not the perceived increase in spaciousness was merely subjective or whether it had a scientific basis, the Lateral Early Energy Fraction (LEF) and the Inter Aural Cross Correlation Coefficient (IACC) were measured in accordance with conventional measurement techniques in the first and second experiments. The nature of the LEF and IACC is explained more fully below.

The subjective quality of the sound produced by the different equipment used in the experiments was also considered in the listening tests. In the first experiment (stereophonic) the sound pressure levels of the distributed mode and cone loudspeakers were set to be substantially the same value at the measuring microphone and it was subjectively considered that the quality of the sound from the combined loudspeakers was better than the quality of sound produced by the cone loudspeakers alone or by the distributed mode loudspeakers alone.

In the second experiment, the sound pressure level of the distributed mode loudspeaker was set to be 4.2 decibels less than the sound pressure level produced by the cone loudspeaker (as measured at the microphone). This Figure was selected after trying a number of different relative sound pressure levels. The quality of the sound produced by the combined loudspeakers was also considered to be better than that produced by the cone loudspeakers alone or the distributed mode loudspeaker alone.

In the third experiment, the effect of varying the relative sound pressure levels of the distributed mode and cone loudspeakers on the subjective quality of the sound was tested and it was found that driving the distributed mode loudspeakers at 5 decibels+/−3 decibels less than the cone loudspeakers gave optimum perceived quality and this quality was found to be better than that perceived when listening to the distributed mode loudspeaker or to the cone loudspeaker alone.

The third experiment also included measurements to determine the frequency responses of the two loudspeakers alone and the frequency response of the combined loudspeaker. Frequency responses of the combined loudspeaker were determined for a number of different relative levels at which the loudspeakers were driven. It was found from these experiments and calculations that frequency response curves for the combined loudspeakers could be obtained which were smoother than the frequency response of the distributed mode loudspeaker alone.

Each of the three experiments will now be described in more detail.

Details of First Experiment (Stereo)

The first experiment was conducted under the following conditions and with the following equipment:
(a) The room was a typical dry room with extra absorption panels randomly placed on the sides and back wall. The room size was 6.87 m long×4.6m wide×2.79m high=volume of 88.17 cubic meters.
(b) The loudspeakers and Microphone were located at apices of an equilateral triangle. The distance between loudspeakers and microphone was 2 Meters (each side of the triangle=2 meters). The loudspeakers were positioned spaced from the walls of the room.
(c) The loudspeakers consisted of two conventional cone loudspeakers and two distributed mode loudspeakers.
(d) The conventional cone loudspeakers were the Genelec model 1029A 40W monitors with integrated amplifier. Technical data: Bass5″ drive unit; Treble ¾″ metal dome drive unit; Crossover frequency is 3.3 kHz; frequency response 70-18,000 Hz.
(e) The distributed mode loudspeakers were manufactured by Amina Technologies Limited (referred to above) and comprised 610 mm×492 mm aluminium core, polyester skin, 4 exciter (10 w/exciter). Each was a 40 w open back panel. The frequency response was 80 Hz to 20 KHz.
(f) For the LEF measurements, a CALREC Soundfield microphone model ST250 was used. For the IACC measurements used a B+K Head and Torso Simulator (HATS) microphone model 4100 was used.
(g) For these measurements, a Maximum Length Sequence signal was used, the Impulse Response was extracted, and spatial measurements performed on the Impulse Response. The software used was the P.C. version of Cool Edit Pro with the Aurora Plugins.
(h) The distributed mode loudspeaker and the cone loudspeaker were driven to provide substantially equally sound pressure levels at the microphone.

A listener positioned in a listening space, such as a concert hall receives sound energy both directly from the source (for example an orchestra) and after reflection at the boundaries of the listening space. The proportion of the total energy received by the listener which is received after reflection from the boundaries of the listening space within a period of approximately 50 milliseconds after receipt of the direct sound is known as the Lateral Early Energy Fraction (LEF). Since the higher frequencies are absorbed more than the lower frequencies and also generally contain less energy than the lower frequencies, most of the reflected energy is in the lower frequency ranges. LEF is conventionally measured in a number of frequency bands, particularly the following bands:
88 to 176 Hz (known as the 125 octave band)
176 to 353 Hz (known as the 250 octave band)
353 to 707 Hz (known as the 500 octave band)
707 to 1,414 Hz (known as the 1,000 octave band)

It is widely considered that, within limits, the higher the LEF in these frequency bands the greater the impression of spaciousness, in the environment of a concert hall. Since the object of the invention is to create an improved impression of spaciousness, measurements of the LEF of the combined sound field created by driving the distributed mode loudspeakers and cone loudspeakers simultaneously were made and compared to measurements of the LEF when the distributed mode and cone loudspeakers were driven separately.

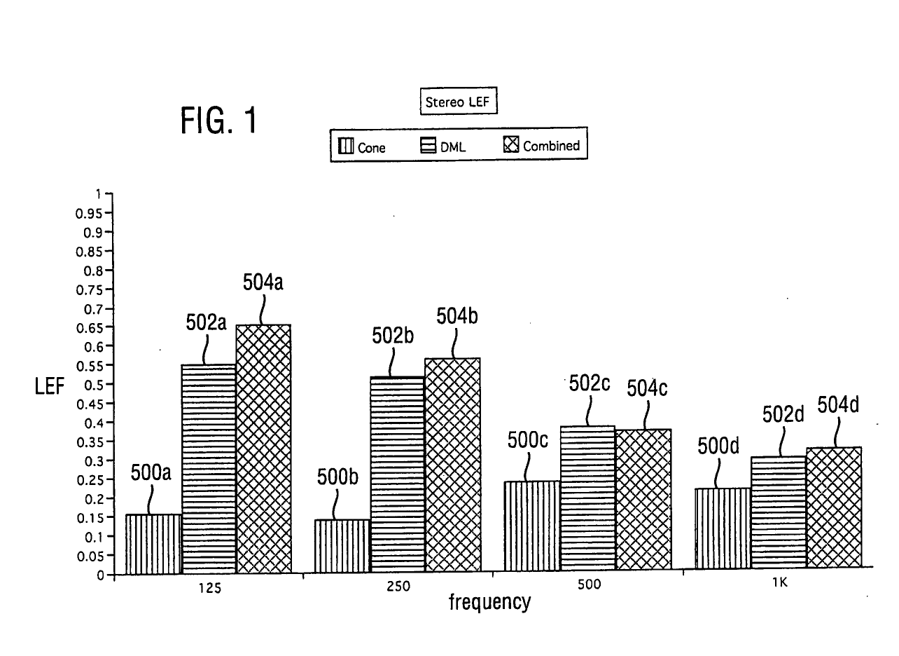

FIG. 1 is a bar chart showing the results. As can be seen in that Figure, the vertically hatched bars 500a, 500b, 500c and 500d respectively show the LEF for the cone loudspeakers alone in each of the above defined octave bands. Horizontally hatched bars 502a to 502d show the LEF for the distributed mode loudspeakers alone in the same octave bands. Cross hatched bars 504a to 504d show the LEF with the combined distributed mode and cone loudspeakers in accordance with the present invention.

As can be seen in FIG. 1, the LEF for the sound field produced by the combined distributed mode and cone loudspeakers in accordance with the invention is markedly higher in each of the octave bands than the LEF in the sound field produced from the cone loudspeaker alone. Thus, FIG. 1 shows that the subjectively perceived marked increase in the impression of spaciousness achieved with the combined loudspeakers in accordance with the invention compared to the cone loudspeakers is consistent with the increase in LEF in the octave bands referred to which, in turn, is consistent with the widely held opinion that increasing the LEF in these frequency bands provides an increase in the impression of spaciousness in the concert hall environment. In other words, the sound field generated by the combined loudspeakers in accordance with the invention in the first experiment differs from the sound field generated by the cone loudspeakers alone in that then is an increase in the value of an important parameter (LEF) which is considered to be associated with improved impressions of spaciousness. It is considered that this is confirmation that the increase in spaciousness perceived in the subjective listening tests referred to above arises from the creation of a physically different sound field when the combination in accordance with the invention is used as compared to that with cone loudspeakers alone.

It can also be observed that in the 125 and 250 octave frequency bands the magnitude of the difference in LEF between the combined loudspeakers and the cone loudspeakers is substantially greater than the difference in LEF in the 500 and 1,000 octave frequency bands. This characteristic is associated with increased warmth in the sound. Expressed differently, if the magnitude of the difference in LEF in each of the four octave frequency bands shown in FIG. 1 were the same, this would be indicative of an increase in spaciousness but not an increase in the warmth of the sound.

It will also be noted from FIG. 1 that the LEFs of the distributed mode loudspeakers alone are greater than those of the cone loudspeakers alone in all four frequency bands. In the 125 and 250 octave frequency bands the LEFs of the distributed mode loudspeakers alone are less than those of the combined loudspeakers. In the 500 and 1,000 octave bands the LEFs of the distributed mode loudspeakers alone and the combined loudspeakers are of a similar magnitude, the differences shown in these octave bands being almost certainly, of themselves, imperceptible. These results suggest, as confirmed by the subjective listening tests, that the increase in spaciousness using the combined loudspeakers in accordance with the invention compared to the distributed mode loudspeakers is not so great as compared to the cone loudspeakers alone and that the distributed mode loudspeakers provide greater spaciousness than the cone loudspeakers. However, the importance of the invention is in achieving a substantial increase in spaciousness over that obtained with cone loudspeakers alone whilst maintaining fidelity. It will be recalled that distributed mode loudspeakers are not yet in wide use in applications requiring the highest levels of fidelity.

The Inter Aural Cross Correlation Coefficient (IACC) is a measure of the degree of correlation between the sound pressure signals received in the two ears of a listener. IACC is consequently conventionally measured using a dummy head having apertures in it in the positions of the human aural passages and a small microphone in each aperture. It is widely considered that low values of this correlation coefficient in one or more of the 1,000, 2,000 and 4,000 octave frequency bands is indicative of increased spaciousness, the values of these bands being as follows:
1,000 band: 707 to 1,414 Hz (as already indicated above)
2,000 band: 1,414 to 2,825 Hz
4,000 band: 2,825 to 5,650 Hz

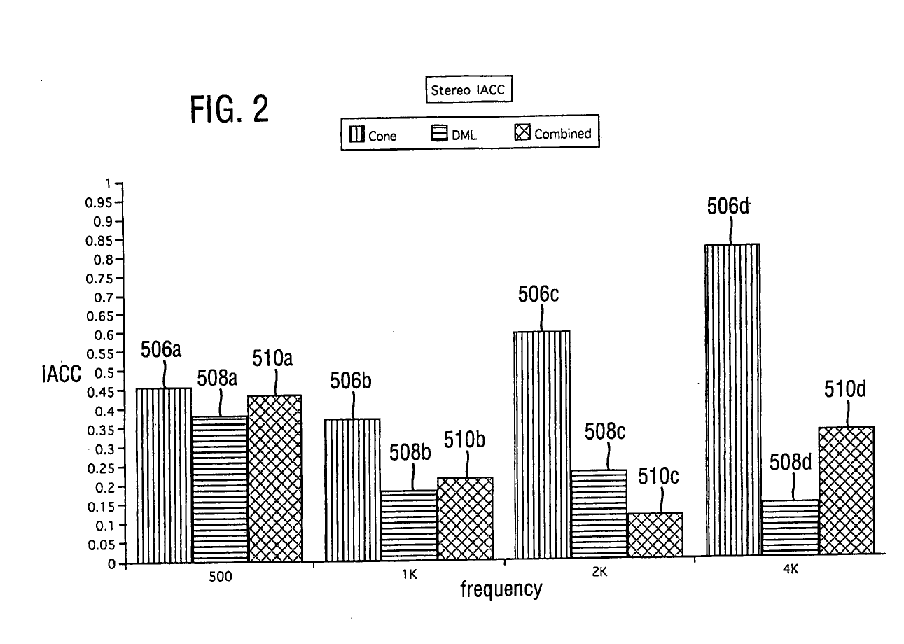

FIG. 2 is a bar chart showing the results of IACC measurements performed in the first experiment. In FIG. 2, the vertically hatched bars 506a to 506d, the horizontally hatched bars 508a to 508d and the cross hatched bars 510a to 510d show respectively the IACCs of the cone loudspeakers alone, distributed mode loudspeakers alone and the combination of both in accordance with the invention, in each of four octave bands, namely the 500 octave band (described above with reference to LEF) and the 1,000, 2,000 and 4,000 octave bands. As can be readily seen from the drawing, the value of the IACC for the combined loudspeakers in accordance with the invention is markedly smaller than that of the cone loudspeakers alone in the 1,000, 2,000 and 4,000 octave bands. This, as with the LEF values, again is indicative of an increase in spaciousness in the sound because as already explained, the lower the value of this coefficient in these frequency bands the greater the impression of spaciousness.

Although FIG. 2 includes IACC measurements in the 500 octave band, these are in fact not relevant because, as will be appreciated, the wave length of the sound energy in this frequency band is such that a high correlation factor is to be expected in the energy received by the two ears of a listener.

Thus, it can be seen that both LEF and IACC measurements on the stereophonic equipment used in the first experiment are consistent with the subjective impression of spaciousness observed in the listening tests.

Details of Second Experiment (Mono)

The second experiment was conducted under the following conditions and with the following equipment:
(a) The room was acoustically treated to absorb sound above 10,000 Hz—average Reverberation Time 0.3 Sec. The room size was 5.6 m long×3.2 m wide×2.4 m high=volume of 43.28 cubic meters.
(b) The microphone in these measurements was located 1.5 meters on axis from the loudspeakers. The front surface of the distributed mode loudspeaker was approximately in vertical alignment with the back surface of the casing of the conventional cone loudspeaker.
(c) The cone loudspeaker was a Tannoy Near Field Dual-Concentric Monitor Model 6NFM Mark II having a frequency response of 44 Hz to 20 KHz. The advantage of this unit is that the HF and LF are at the same axis point for measurements. The distributed mode loudspeaker panel used was manufactured by Amina Technologies Limited and comprises a 500×700 mm resin dipped paper honeycomb core and skin with 4 exciters (10 w/exciter). It was a 40 w open back panel with a frequency response of 80 Hz to 20 KHz.
(d) For the LEF measurements an AKG C34 Variable Polar Microphone was used. For the IACC measurements, a Neuman Binaural Head was used.
(e) Again the Impulse Response and the spatial data was extracted from a Maximum Length Signal. The software used was the MLSSA P.C. software.
(f) Using a separate amplifier, the DML panel was set 4.2 dB lower than the Tannoy.

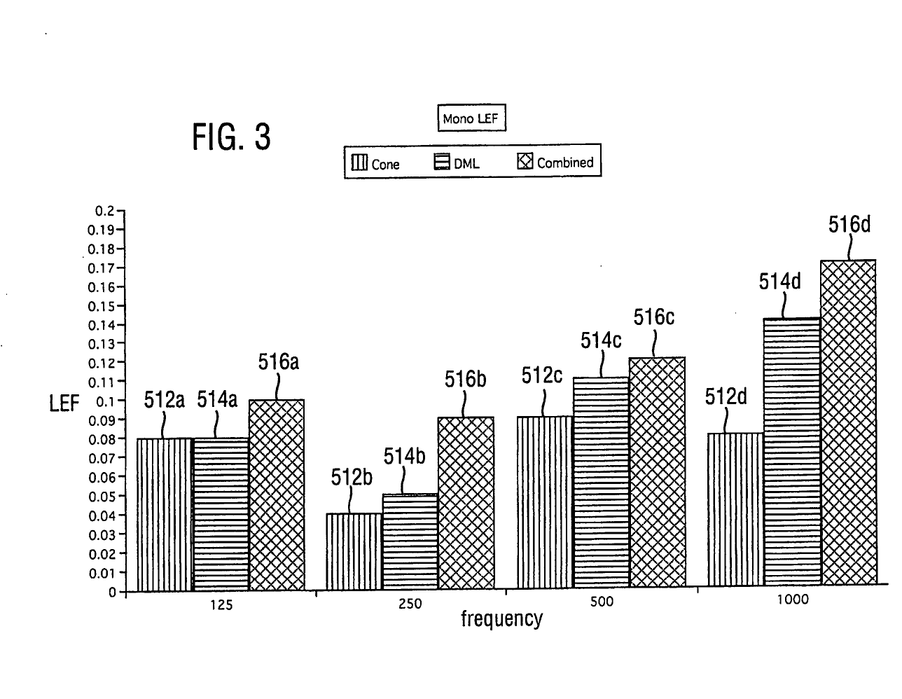

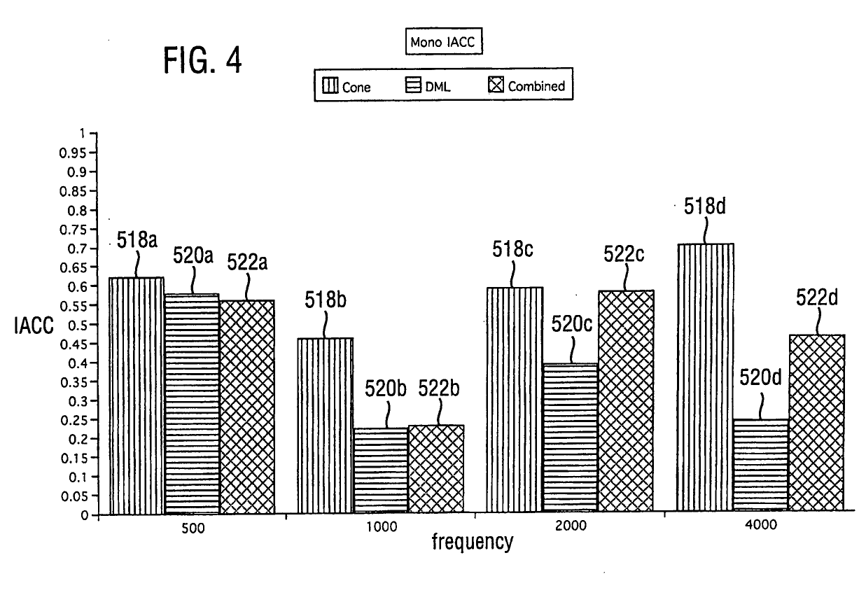

FIGS. 3 and 4 are bar charts showing the LEFs and IACCs measured in the second experiment. The hatching of the bars has the same significance as in FIGS. 1 and 2. Thus, bars 512a to 512d in FIG. 3 and bars 518a to 518d in FIG. 4 represent respectively the LEFs and IACCs for the cone loudspeakers alone; bars 514a to 514d in FIG. 3 and bars 520a to 520d in FIG. 4 represent the LEFs and IACCs for the distributed mode loudspeaker alone; and bars 516a to 516d and 522a to 522d in FIGS. 3 and 4 respectively represent the LEFs and IACCs for the combined digital mode and cone loudspeakers in accordance with the invention. As in FIGS. 1 and 2, each bar in FIGS. 3 and 4 represents the relevant value in a specific octave frequency band, as indicated in the drawings.

Examination of FIG. 3 will show that the LEF values for the combined loudspeakers in accordance with the invention are higher in each octave frequency band than the LEFs for the conventional cone loudspeaker alone and for the distributed mode loudspeaker alone. This is consistent, as previously explained, with the perceived increase in spaciousness observed in the subjective tests. The fact that the magnitude of the difference between bars 516b and 512b is greater than the magnitude of the difference between bars 516c and 512c (LEF values in the 250 and 500 octave bands) is indicative of a marked improvement in the warmth of the sound.

FIG. 4 shows that in the 1,000 and 4,000 octave bands, the IACC of the combined loudspeakers in accordance with the invention is significantly lower than that of the cone loudspeakers alone. This is consistent with the observed increase in spaciousness, However, in the 2,000 octave band the IACC values 518c and 522c are almost the same. As described with reference to FIG. 2, the IACC values shown in FIG. 4 of the 500 octave band are not relevant.

FIGS. 3 and 4 together are consistent with the surprising and marked increase in the impression of spaciousness perceived in the subjective tests with the mono system used in the second experiment.

Details of Third Experiment (Mono)

This experiment was performed in an environment, and with equipment, different from the environment and equipment of the first and second experiments described above. The experiment consisted of subjective tests using a single channel (mono) with the loudspeaker in an unfavourable acoustic (as already described above), and frequency response measurements performed in an anechoic chamber. Measurements of LEF and IACC were not carried out in this experiment.

The conventional cone loudspeaker used throughout these measurements was a JBL LSR32 passive studio monitor comprising three drive-units covering a frequency range of approximately 30 Hz to 20 kHz. The DML was manufactured by Amina Technologies Ltd. The DML panel comprised a resin dipped paper honeycomb core with a resin impregnated fibreglass skin and measured 60 cm H 60 cm. There were four electromagnetic exciters and the frequency response was 80 Hz to 20 KHz.

The DML panel was placed on top of the conventional loudspeaker and attached with strong double-sided adhesive tape. Pink noise was used as the test signal for all measurements ensuring adequate signal-to-noise ratios at all frequencies of interest (pink noise is a broadband random signal which contains equal signal energy per octave of bandwidth). The output signal from the signal generator was connected to the inputs of a two-channel power amplifier via a pair of universal filter sets to allow tailoring of the frequency range of the signals fed to each loudspeaker. The relative output levels of the two loudspeaker were adjusted using a switchable attenuator in line with the drive to the amplifier powering the conventional loudspeaker.

On-Axis Frequency Response

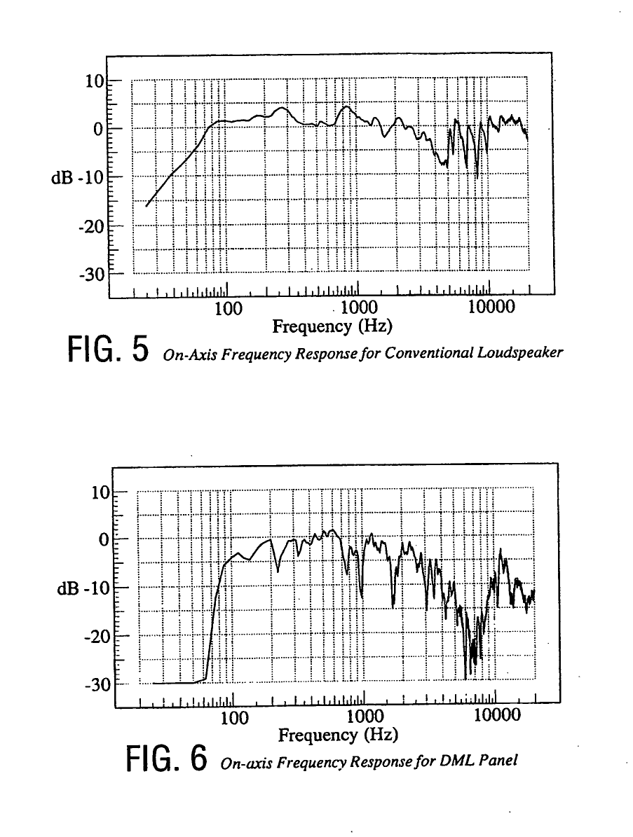

FIG. 5 shows the magnitude of the on-axis frequency response of the conventional cone loudspeaker, and FIG. 6, that for the DML panel. The low-frequency response of the DML panel was cut below 100 Hz in accordance with the manufacturer's recommendations. An in-line attenuator was adjusted to give approximately the same on-axis level from the two loudspeakers in the range of frequencies from 500 Hz to 5 kHz.

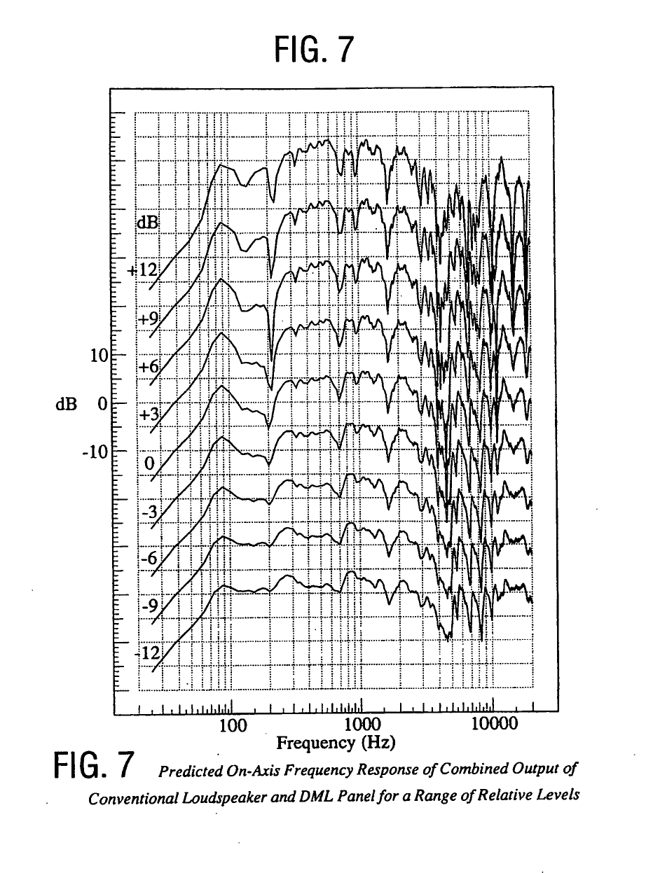

The frequency responses shown in FIGS. 5 and 6 were summed on a computer both with and without regard for phase. A comparison between the resultant frequency responses and a measurement of the frequency response obtained when the loudspeakers were combined clearly showed that phase addition, and hence interference, occurs between the two loudspeakers. It follows that, surprisingly, the frequency response of the combined output of the two loudspeakers can be accurately determined by summing the individually-measured responses with regard for phase. This being the case, it is possible to determine the response of the combination with arbitrary relative output levels. FIG. 7 shows the frequency response of the combination, determined by summing, on a computer as just described, with the level of the DML varied from −12 dB to +12 dB in 3 dB steps relative to that of the conventional loudspeaker.

Subjective Appraisal

Subjective tests were carried out on the two loudspeakers using the same equipment as used in the measurements, but in a semi-reverberant space (intercepting corridors as described above) instead of the anechoic chamber.

All listening was carried out in single-channel mono using a variety of commercially available music recordings played from compact discs. First a marked change in spaciousness was perceived as the DML panel was switched in and out. The subjects agreed that the addition of the panel improved the feeling of spaciousness compared to the conventional cone loudspeaker alone. Second, the relative levels of the two loudspeakers were varied until the subjects agreed on an optimum level for the perceived improvement. This was carried out using the ‘balance’ control on the amplifier to maintain a constant overall level. The subjects agreed on an optimum level setting of −5 dB output from the DML panel relative to the level used in the above measurements (equal level from 500 Hz to 5 kHz). The subjects agreed on this value within V3 dB.

A further test involved establishing thresholds of relative level, beyond which no change in sound could be detected as one loudspeaker was switched in and out while the other remained constant. The levels were quickly determined as about −35 dB detection threshold for the DML panel and −20 dB for the conventional loudspeaker.

Discussion

The frequency response measurements clearly show that the DML panel has a less smooth frequency response than the conventional cone loudspeaker. This is not entirely surprising when the different radiation mechanisms are considered. The DML panel also suffers a pronounced dip in response at around 7 kHz. What is surprising, however, is the degree to which the DML panel and conventional loudspeaker interfere. DML panels radiate sound the way they do because the vibration field over the surface of the panel is approximately diffuse in nature. Therefore one may quite reasonably expect there to be no particular phase associated with the radiated sound field; however, the results of these measurements show that, at least at a single point in space and over a narrow frequency band (but for all audio frequencies), the panel has a measurable and repeatable phase response which gives rise to constructive interference with the sound radiation from another loudspeaker.

FIG. 7 shows the frequency response of the combined output of the two loudspeakers when the level of the DML panel is varied relative to that of the conventional cone loudspeaker. As could be expected, low levels of DML output have little effect on the response of the conventional cone loudspeaker and high relative levels show the response dominated by that of the panel. The most interesting point to note about this Figure however, is the relative level at which the otherwise smooth response of the conventional cone loudspeaker is upset by interference from the output of the DML. The Figure shows that for relative levels above −3 dB, the response is, in this experiment, adversely affected by the panel, but for lower levels, this is not the case. This is in accordance with the subjective observation that a relative level of −5 dB is about optimum for preferred sound quality; it is possible that for higher relative levels of DML output the improvement in spaciousness is a trade-off against a poorer frequency response.

Summary of Conclusions from this Experiment

As with the first and second experiments, the subjective tests indicated a marked increase in the impression of spaciousness, this being in a monaural system with the loudspeaker in an unfavourable acoustic. The frequency response measurements and calculations indicated that the combined loudspeakers in accordance with the invention may achieve, with appropriate levels of driving signal, a frequency response significantly better than the distributed mode loudspeaker alone.

### Practical Embodiments

As will be appreciated from the above discussion of the experiments which have been conducted, both the subjective tests and the scientific measurements, the invention provides a practical and simple solution to the problem of enhancing the spaciousness of sound produced by loudspeakers, in particular making it possible to utilise a high quality wide frequency range pistonic loudspeaker and enhance the spaciousness of the sound produced, without losing the high fidelity of the sound, by the addition of distributed mode loudspeakers and without the need for additional signal channels or complex signal encoding.

In putting the invention into practice, the distributed mode and pistonic loudspeakers must operate over a common part of the audible frequency band. Preferably, both loudspeakers operate over substantially the whole of the audible frequency band, for example the pistonic loudspeaker may operate from 20 Hz to 20 KHz and the distributed mode loudspeaker may operate from about 100 Hz to 20 KHz or, when the art of distributed mode loudspeakers is further developed, both loudspeakers might operate over the whole of the audible frequency range i.e. 20 Hz to 20 KHz. It is within the scope of the invention for narrower frequency bands to be used dependent upon circumstances, such as cost and intended use. For example, the distributed mode loudspeaker could be restricted to a much narrower frequency band than indicated above, for example the frequency band from 100 to 1,000 Hz, or the frequency band from 200 to 2,000 Hz or a frequency band covering one or more octaves within the range up to 4,000 Hz or up to 6,000 Hz. By way of a further specific example, the frequency band of the distributed mode loudspeaker or loudspeakers might be from 100 to 6,000 Hz and the frequency band of the pistonic loudspeakers might be from 800 to 8,000 KHz.

As a further alternative, provided the distributed mode and pistonic loudspeakers operate over a common part of the frequency range, the highest frequency of the pistonic loudspeakers might be substantially lower than the highest frequency of the distributed mode loudspeakers so that in the higher frequencies the tweeter is constituted by the distributed mode loudspeaker.

In general, therefore, the frequency range of the distributed mode loudspeaker can be wider than or narrower than that of the pistonic loudspeaker; the lower extremity of the frequency range of the distributed mode loudspeaker may be lower than or higher than the lower extremity of the frequency range of the pistonic loudspeaker; and the upper extremity of the frequency range of the distributed mode loudspeaker may be lower than or higher than that of the pistonic loudspeaker. The best frequency ranges for the pistonic and distributed mode loudspeakers may be determined by experiment dependent upon applications and costs and particular requirements for different uses or different markets.

A number of practical embodiments of the invention will be described below. In most of these embodiments specific frequencies will not be given. These should be taken to be selected from the ranges foreshadowed in the above discussion dependent upon the circumstances of the particular product to be designed in accordance with the description of the embodiments.

Also, the location of the loudspeakers or sound reproducing devices of the following embodiments when in use will not be described. It will be for the user or installer of the system to decide upon the best location in any particular listening space. Where the distributed mode loudspeaker is physically a separate unit from the pistonic loudspeaker, the two loudspeakers may be positioned next to each other, on top of one another or in other locations, for example with the distributed mode loudspeaker behind or to the side of the area intended for the listener. In this connection, it should be understood that, whereas the positioning of the loudspeakers in surround sound systems is critical and is dependent upon the encoding of the signals in the different channels, which encoding is performed on the assumption that the loudspeakers will be in pre-defined positions, this constraint does not apply to the invention.

It should also be understood that tests (not referred to in the above description of the experiments) have indicated that the introduction of a delay between the output of the pistonic and distributed mode loudspeakers may be employed and in particular the signals applied to the distributed mode loudspeakers may be delayed relative to those applied to the pistonic loudspeakers. Where a delay is applied, it should in general never exceed 80 msecs and preferably it should not exceed 35 msecs. The introduction of such delays has been found in informal tests to enhance the Aimaging@ or Alocalisation@ of the sounds in stereophonic applications or surround sound applications. Such improvements in imaging and localisation improve the musical intelligibility, when music is listened to.

It is considered that this improvement arises because, as a result of the delay, the transients in the sounds from the pistonic loudspeakers are not masked by the transients from the distributed mode loudspeakers but the transients from the distributed mode loudspeakers are masked by the transients from the pistonic loudspeakers.

Although in the above discussion in relation to LEF and IACC and in relation to the effect of delays theoretical explanations underlying the effects have been given, it should be understood that the applicant is not bound by these explanations. The explanations given are based upon current knowledge and measurement techniques in the audio field but it is well recognised that the psychoacoustic effects in human beings of the sounds to which they are subjected is an extremely complex subject and accurate explanations are difficult (or in some situations impossible) to give.

A number of practical embodiments of the invention will now be described.

### First Embodiment

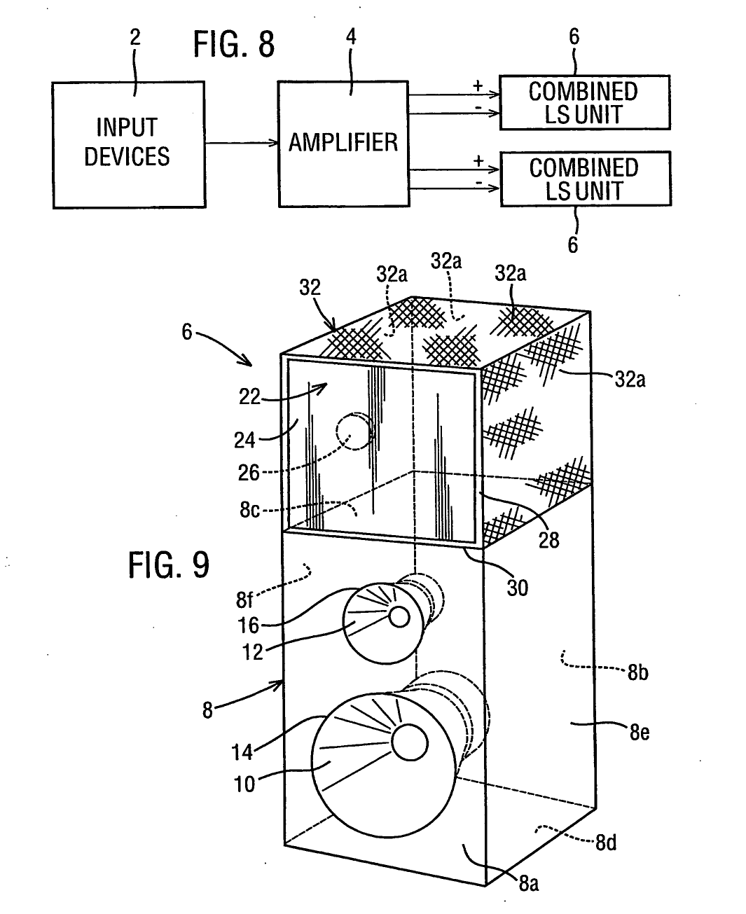

FIGS. 8 to 12 show a stereophonic sound reproduction system according to a first embodiment of the invention.

As shown in FIG. 8, the system comprises a number of input devices 2, such as a CD player, a stereo FM tuner and/or a stereo tape player; a stereophonic amplifier unit 4 of conventional construction and thus comprising the usual pre-amplifiers, control circuits and power amplifiers, and a pair of loudspeaker units 6 connected respectively to the left and right channel outputs of the amplifier 4, for reproducing stereophonic sounds such as music. The loudspeaker units 6 each include both conventional cone loudspeakers and a distributed mode loudspeaker driven in accordance with the teaching of the invention. The two loudspeaker units 6 are identical to each other.

As shown in FIG. 9, each loudspeaker unit 6 comprises a casing 8 containing a conventional full frequency range two-way cone loudspeaker system comprising a base/mid-range speaker 10 and a tweeter 12. Each of the cone loudspeakers 10 and 12 includes a respective electromagnetic drive unit which may be of the moving coil or moving magnet type for driving the respective cones. The casing 8 has front, rear, top, bottom and side panels 8a, 8b, 8c, 8d, 8e, 8f. The front panel 8a has apertures 14, 16 behind which the cones of the loudspeakers 10, 12 are located. The cones of the loudspeakers 10, 12 close the apertures 14, 16 so that, as is conventional, the casing 8 forms a closed chamber in which the cone loudspeakers 10 and 12 are arranged so that these loudspeakers generate sound in free air in a conventional manner. The interior of the closed chamber in the casing 8 may contain any conventional structures or damping material.

A distributed mode loudspeaker 22 is secured in a vertical orientation on top of the casing 8 and comprises a loudspeaker panel 24 and an electromagnetic actuator 26 attached to the rear of the panel 24. A rectangular frame 28 secured to the casing 8 along one edge 30 supports the panel 24 in approximately the same plane as the front of the casing 8 and in a manner which permits the panel 24 to be excited, by the actuator 26, into resonant distributed mode vibrations in a well known manner.

The panel 24 and frame 28 form the front wall of a housing 32 which is positioned on top of the casing 8 and of which the side, rear and top walls 32a are all made of metal mesh containing a multitude of apertures so that sound generated from the rear surface of the panel 24 will be transmitted substantially freely through the mesh walls 34 to free air.

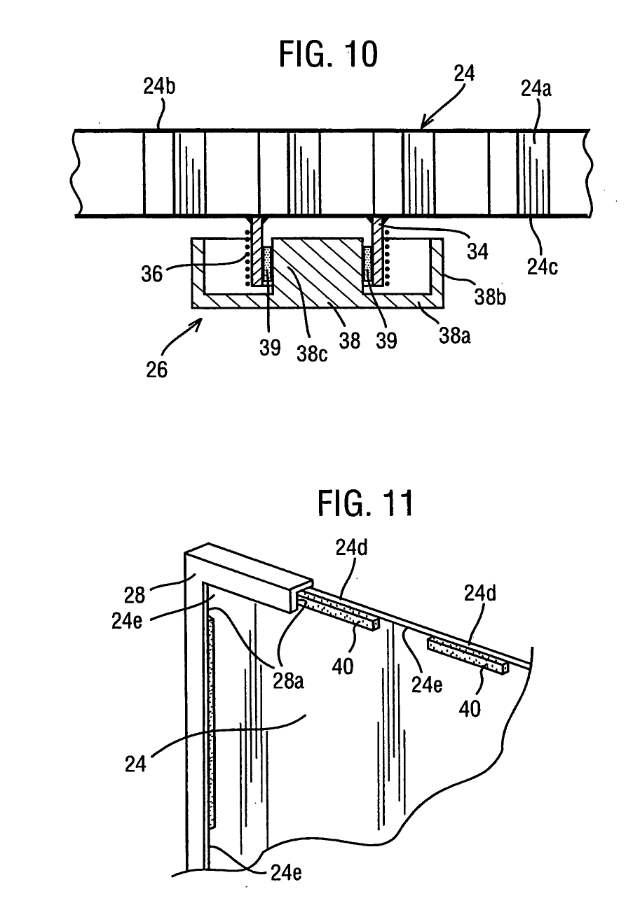

The exciter 26 comprises a non-magnetic light weight rigid cylindrical former 34, an electrical coil 36 wrapped on and supported by the former 34 and a magnet 38, all of which are shown in diagrammatic cross section in FIG. 10. The magnet 38 is essentially cup-shaped and comprises a circular end or bottom wall 38a, a cylindrical side wall 38b and a solid cylindrical central core 38c. Soft compliant material 39 is secured by adhesive between the exterior surface of the central core 38c of the magnet 38 and the interior cylindrical surface of the former 34, to support the magnet compliantly relative to the former so that when the coil 36 is energised by an alternating electrical signal, the resulting electromagnetic forces acting between the coil 36 and the magnet 38 cause relative vibratory movement between the former 34 and the magnet 38. The magnet is, as known in the art of distributed mode loudspeakers, unsupported other than as described above but it is substantially heavier than the former in order that, as a result of the mechanical inertia of the magnet 38 due to its weight, vibrations are transmitted to the panel 24. As is known in the art of distributed mode loudspeakers, it is possible to provide additional support for the magnet 38 (no such additional support being shown in FIG. 10 or included in the current embodiment) but this must nevertheless permit vibratory movement of the magnet.

The panel 24 as diagrammatically illustrated in FIG. 10 comprises an interior honeycomb structure 24a containing passages extending from front to rear of the structure, these passages being closed by front and rear surface layers 24b and 24c respectively. The structure is selected, in accordance with the design principles for distributed mode loudspeakers, to be of light weight and, as already described above, to be capable of being set into resonant distributed mode vibrations in the form of bending waves by activation of the exciter 26 which, in accordance with the design principles for distributed mode loudspeakers, is appropriately designed and positioned on the panel 24 for this purpose.

As already indicated, in order to permit these vibrations, the panel 24 is mounted compliantly in the frame 28. FIG. 11 illustrates an example of a suitable compliant mounting means for this purpose, namely a soft foam strip 40 adhesively secured between edge regions 24d of the panel 24 and a rear face 28a of the frame 28 (shown as of L-shaped cross section). The strip 40 has discontinuities therein so that edge regions 24e of the panel 24 are free to vibrate without there being any attachment to the frame 24 at the regions 24e. In accordance with the design principles for distributed mode loudspeakers, the selection of the regions 24d and 24e of the panel 24 will be made so as to optimise the ability of the panel to be excited into resonant distributed mode vibrations.

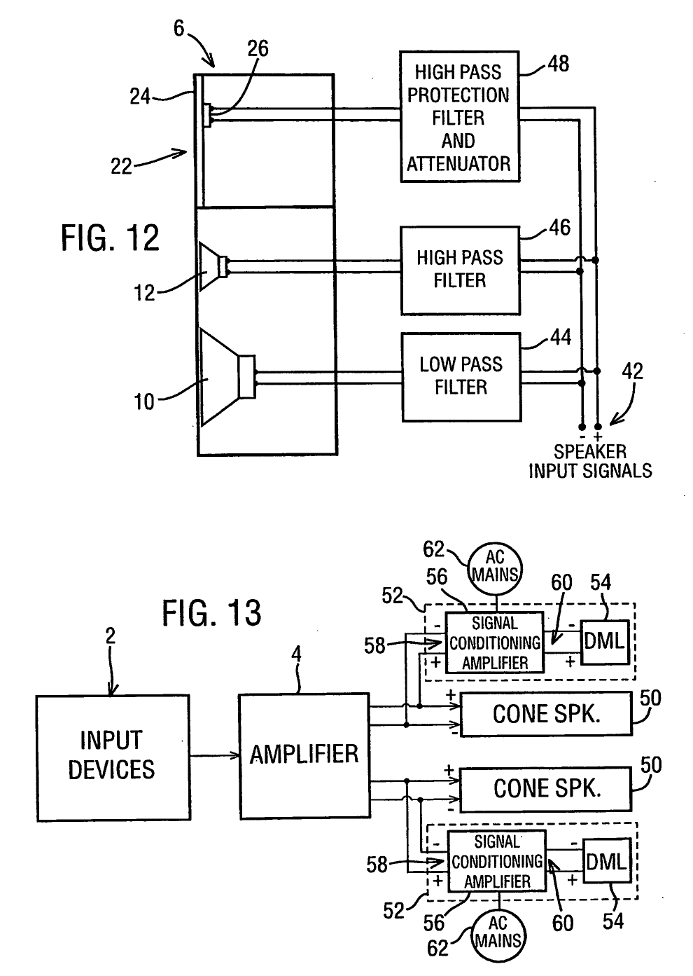

As shown diagrammatically in FIG. 12, each loudspeaker unit 6 includes a pair of input terminals 42 which are for connection, via appropriate wires, to the output of the conventional amplifier 4 shown in FIG. 8 and which supply driving signals to the cone loudspeakers 10 and 12 and the distributed mode loudspeaker 22. These signals are applied to the woofer and tweeter cone loudspeakers 10 and 12 respectively through a low pass filter 44 and a high pass filter 46, which jointly constitute a conventional crossover circuit, and are supplied to the distributed mode loudspeaker 22 through a high pass protection filter and attenuation circuit 48. The cone loudspeakers 10 and 12 and the filters 44 and 46 are designed and arranged so that the loudspeakers 14 and 16 jointly reproduce substantially the full audio frequency range from say 20 Hz to 20 KHz and thus constitute a conventional cone loudspeaker system. The distributed mode loudspeaker 22 with the high pass protection filter contained in circuit 48 is designed and arranged to produce as much of the full frequency range as practical, taking into account the fact at the present state of technology distributed mode loudspeakers do not, at least in general, effectively reproduce sounds having a frequency of less than 100 Hz. Thus, the circuit 48 is arranged to cut off signals having a frequency of less than 100 Hz so that the distributed mode loudspeaker 22 may reproduce the frequencies within the range 100 Hz to 20 KHz. An attenuator is included in the circuit 48 so that the distributed mode loudspeaker 22 produces a sound pressure level less than that of the sound pressure level produced by the cone loudspeakers 14 and 16. For example, (as explained above in the context of the experiments that were conducted) a sound pressure level of −5 db+ or −3 db is the preferred sound pressure level difference.

The embodiment of FIGS. 8 to 12 may thus provide, if constructed of components of appropriate quality, a high fidelity music reproduction system with improved spaciousness compared to that obtainable with conventional loudspeakers alone, distributed mode loudspeakers alone or an arrangement in which a distributed mode loudspeaker is used merely as a tweeter in combination with a conventional loudspeaker used as a woofer.

Preferably, the high pass protection filter attenuator circuit 48 is adjustable by the user so that he may set different levels of attenuation according to preference and room acoustics by trial and error. Preferably also, the circuit is adjustable to enable it to introduce a delay in the signal applied to the distributed mode loudspeaker in the range 0 to 35 msec.

In use, the loudspeakers of the system described with reference to FIGS. 8 to 12 may be positioned in a conventional manner but it should be ensured so far as possible that the distributed mode loudspeakers can radiate backwards as well as forwards i.e. the rear of the loudspeakers should not be positioned directly against a wall or other item which would prevent rearward propagation of the sound from the distributed mode loudspeakers.

### Second Embodiment

FIG. 13 shows an alternative embodiment of the invention in which a conventional hi-fidelity music reproduction system comprising conventional input devices as previously described, a conventional stereo amplifier and a pair of conventional cone loudspeakers 50 is supplemented by a pair of auxiliary sound reproduction units 52, one for the right channel and one for the left channel, which convert the conventional hi-fidelity system to a system in accordance with the teachings of the present invention.

Each auxiliary unit 52 comprises a distributed mode loudspeaker 54 and a signal conditioning amplifier 56 having input terminals 58, connected to a respective one of the left and right loudspeaker outputs of the amplifier 4, and output terminals 60 connected to the respective distributed mode loudspeaker 54. Each signal conditioning amplifier 56 is mains powered as indicated by reference number 62. For convenience, the input terminals 58 may be connected by short lengths of wire to the terminals of the loudspeaker units 50 respectively, thereby avoiding additional long wires connected between the outputs of the amplifier 4 and the inputs of the auxiliary units 52.

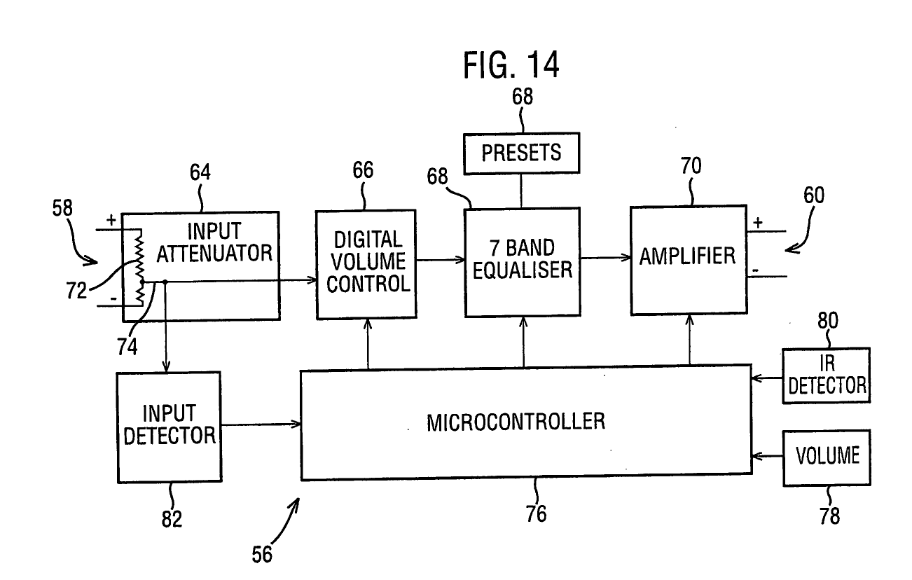

FIG. 14 is a block diagram of each signal conditioning amplifier 56. As shown, an attenuator 64 is connected to the input terminals 58 and supplies a signal to a digitally controlled volume control circuit 66 whose output is supplied via a seven band equaliser 68 to a power amplifier 70 whose output is connected to the terminals 60.

The attenuator 64 comprises a high resistance value resistor 72 connected across the terminals 58 having a tap 74 to supply the above referred to low level signal to digital volume control 66. The resistance value of the resistor 72 is chosen such that the total impedance arising from the connection of both the signal conditioning amplifier 56 and the loudspeaker 50 across the output terminals of the amplifier 4 is as close as practical to the impedance provided by the loudspeaker 50 alone, so that amplifier 4 is not adversely affected by connecting it to the auxiliary units in addition to the conventional cone loudspeakers 50.

The seven band equaliser includes a number of preset controls 68a for presetting the relative amplification to be applied in seven different frequency bands. The settings of the controls 68a are selected to compensate at least to some extent for any variations in the frequency response of the distributed mode loudspeaker 54 and to cut off any low frequencies, such as frequencies below 100 Hz, which the distributed mode loudspeaker may be unable to reproduce satisfactorily.

A microcontroller 76 controls the digital volume control circuit 66, the equaliser 68 and the power amplifier 70. The microcontroller 76 is, in turn, controlled by a manual volume control device 78 operable by the user of the system and a signal from an infra-red detector 80 responsive to a hand held remote control device (not shown) for adjusting the volume, so that the user of the system may adjust the volume of the sound produced by the distributed mode loudspeaker relative to the volume produced by the cone loudspeaker. To avoid wasting power, the device 56 is constructed so that, when no signal is supplied to it from the amplifier 4, it will enter a power-down mode. An input detector circuit 82 is connected to the tap 74 and in response to detection of a signal appearing at the tap 74 supplies a control signal to the microcontroller 76 which is programmed to thereupon enter a power-up mode at which the circuit will operate.

In the embodiment of FIGS. 13 and 14, the conventional cone loudspeakers 50 operate over the full frequency range and the distributed mode loudspeakers 54 operate over as much of that range as practical, as already discussed in relation to the previous embodiment, and consequently, by adding a pair of auxiliary units to an existing high fidelity sound reproduction system as described with reference to FIGS. 13 and 14, the existing system can be converted to an improved system implementing the invention and providing enhanced spaciousness.

The auxiliary units 52 may thus be made and sold separately from the hi-fidelity system as a whole, so that they may be added to existing hi-fidelity systems. The signal conditioning amplifier 56 may be physically mounted on or in a base or housing which also supports the distributed mode loudspeaker or alternatively may be separate from it.

Further, although FIG. 13 illustrates two separate signal conditioning amplifiers 56, it is alternatively possible to provide a two channel signal conditioning amplifier, with each channel comprising an input attenuator 64, digital volume control 66, equaliser 68 and power amplifier 70 as already described but a single microcontroller controlling both channels. In such an arrangement, the input detector may be connected to both input attenuators and arranged to cause the circuit to enter a power-up mode in response to a signal on either one of the channels or both. Such a two channel signal conditioning amplifier may have all of its components contained in a single housing which may be integrated into a base or supporting housing for one of the distributed mode loudspeakers or alternatively may be constructed as an item separate from the distributed mode loudspeakers. Providing a single microcontroller will also reduce costs.

To simplify as far as possible the act of connecting the auxiliary units 52 into an existing sound reproduction system, each auxiliary unit 52 may be provided with additional output terminals (not shown in the drawings) which are directly connected to the input terminals 58 and which are for connection to the existing conventional cone loudspeakers by a short length of wire (not shown in the drawings) which may be included in the auxiliary unit as made and sold. In the modification where a two channel signal conditioning amplifier is provided as described above, there would be two sets of such additional output terminals, one for each channel.

### Third Embodiment

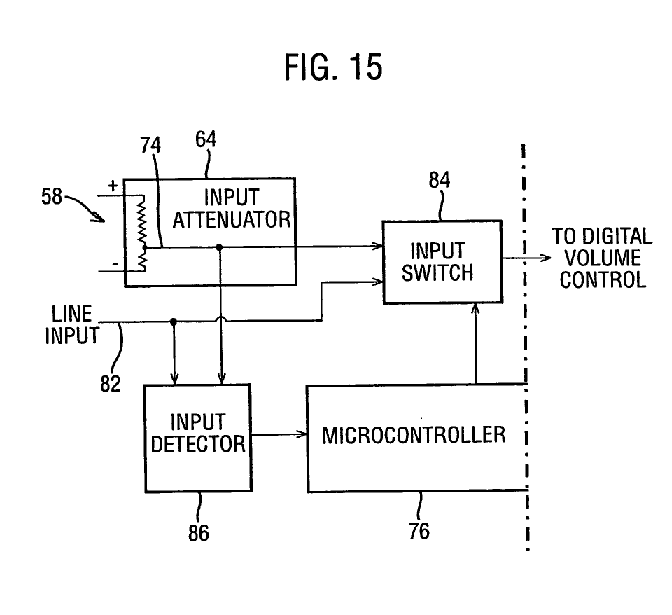

FIG. 15 illustrates a modification to the input end of the circuit shown in FIG. 14 which is to permit the signal conditioning amplifier to receive input not only at high (speaker) level (as is the case in the arrangement of FIG. 14) but also at line level. For this purpose a line level input terminal 82 is provided connected to one input of an input switch 84, whose other input is connected to the output of the attenuator 64. The input detector circuit 80 is replaced by a detector circuit 86 which has two inputs, one connected to the tap 74 and the other to the line input 82. The input detector circuit 86 is arranged to send a signal to the microcontroller 76 indicating when a signal is present at line input 82 or tap 74 and the microcontroller is arranged to interpret this signal to appropriately set the input switch 84 to connect its output either to the line input or to the tap 74. As described with reference to FIG. 14, the microcontroller also causes the circuit to enter power up mode in response to the signal from the input detector 86.

As with the embodiment of FIG. 14, both the left and right channels could be provided in a single unit and controlled by a single microcontroller as already described.

Also, as described above, additional output terminals which are directly connected to the input terminals 58 and which are for connection to the conventional cone loudspeakers 50 may be provided, to simplify the act of connecting the auxiliary units to an existing sound reproduction system.

### Fourth Embodiment

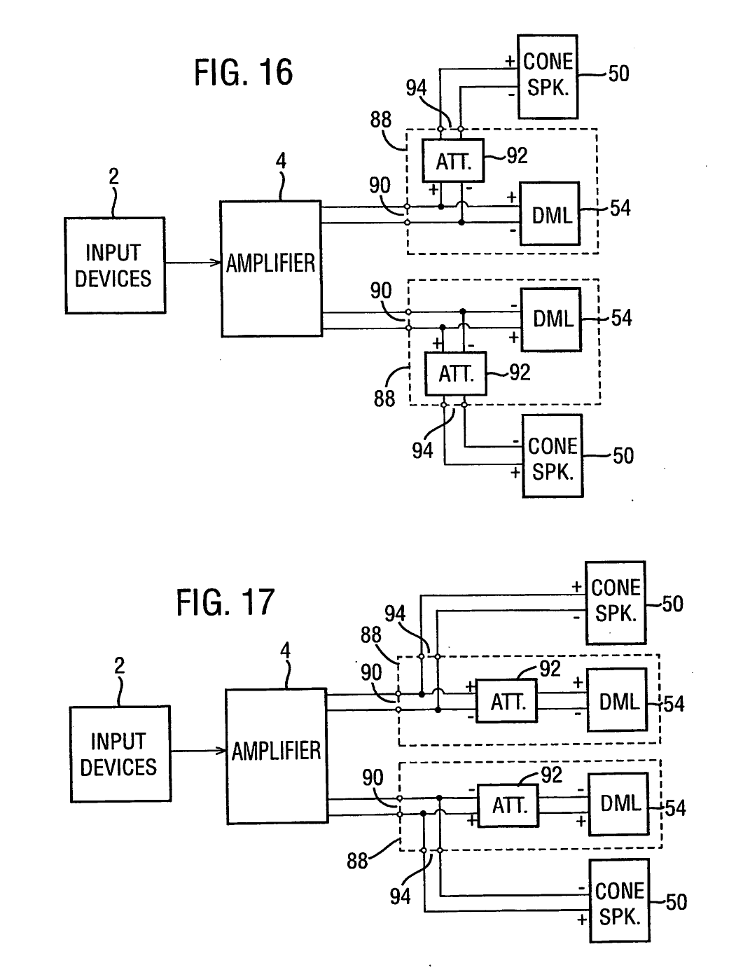

FIG. 16 shows an alternative form of auxiliary unit for converting a conventional hi-fidelity system to an embodiment of the invention. In FIG. 16, the conventional hi-fidelity unit comprises the input devices 2 and conventional amplifier 4 and a pair of conventional cone loudspeakers 50 which, in this embodiment are assumed to be more efficient than the distributed mode loudspeakers to be added to the system. Accordingly, FIG. 16 shows left and right auxiliary units 88 each comprising a distributed mode loudspeaker 54 connected to input terminals 90 and an attenuator circuit 92 connected between the input terminals 90 and output terminals 94 which are for connection to the conventional cone loudspeaker 50.

The arrangement shown in FIG. 16 assumes that the impedance across terminals 90, when all loudspeakers are connected, is within the range of impedance that the amplifier 4 can handle.

### Fifth Embodiment

FIG. 17 is an arrangement similar to that shown in FIG. 16 except that in this arrangement it is assumed that the distributed mode loudspeakers 54 are more efficient than the cone loudspeakers 50. Hence the attenuator circuits 92 are connected between the input terminals 90 and the distributed mode loudspeakers 54 rather than between the input and output terminals 90, 94. As in the case of FIG. 16, it is assumed in FIG. 17 that the total impedance across terminals 90 when all loudspeakers are connected is within the range of impedance that the amplifier 4 can handle.

### Sixth Embodiment

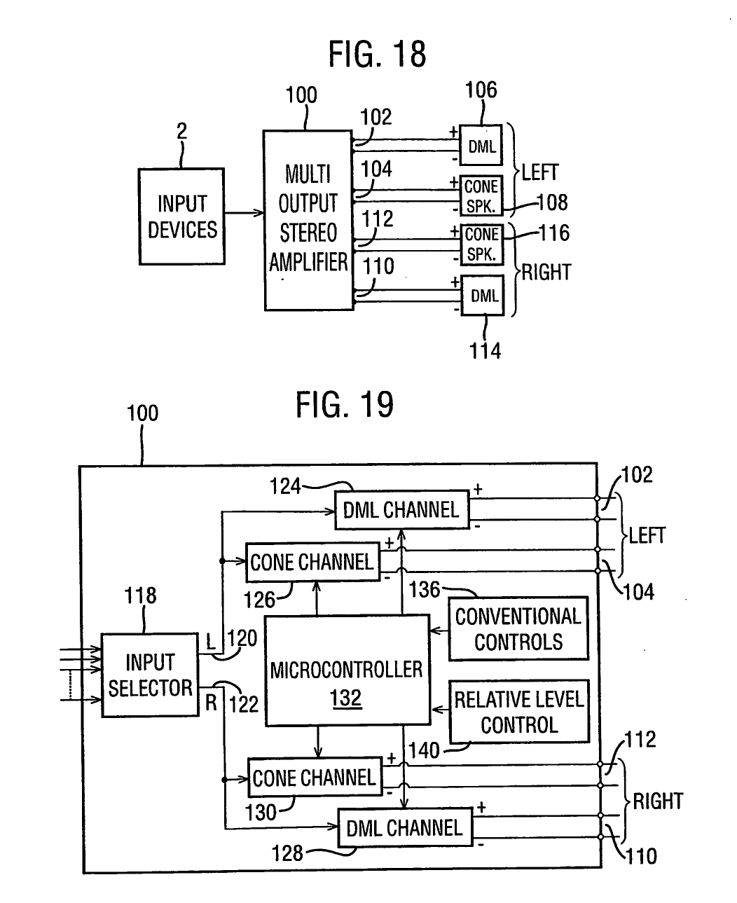

With reference to FIG. 18, a sound reproduction system comprises conventional input devices 2, as previously described, a purpose-built stereophonic amplifier 100 having first and second left channel stereo output terminals 102, 104 connected respectively to a distributed mode loudspeaker 106 and a conventional cone loudspeaker 108, and first and second right channel stereo output terminals 110, 112 connected respectively to a distributed mode loudspeaker 114 and a conventional cone loudspeaker 116. The conventional cone loudspeakers 108 and 116 are both preferably full frequency range loudspeakers and may be, for example, two-way or three-way devices with conventional crossover circuits so that the cone loudspeakers in combination reproduce sounds in the range say 20 Hz to 20 kHz. Also, as previously described the distributed mode loudspeakers 106 and 114 cover as much of the full range as practical, as previously described, preferably producing sounds in the range at least 100 Hz to 20 kHz.

As shown in FIG. 19, the amplifier 100 includes a conventional input selector circuit 118 for receiving user selected inputs from the conventional devices 2 and having left and right output terminals 120, 122 respectively. The left output terminals 120 are connected to the input terminals of both a left distributed mode loudspeaker signal processing channel 124 and a left cone loudspeaker signal processing channel 126 whose outputs are connected respectively to the terminals 102 and 104. The right output terminals 122 of the input selector 118 are connected to the inputs of both a right distributed mode loudspeaker signal processing channel 128 and a right cone loudspeaker signal processing channel 130 whose outputs are connected respectively to the terminals 110 and 112.

The channels 124, 126, 128 and 130 are controlled by a microcontroller 132 which receives control inputs from a set of conventional controls 136 and a relative volume control 140. The conventional controls 136 are arranged to be actuated by a user of the system and may include all of the usual controls such as a left-right balance control, treble and bass controls, graphic equaliser controls etc. The relative volume control 140 is also arranged to be user actuated and is for setting the relative volume between the distributed mode loudspeakers 106 and 114 on the one hand and the conventional cone loudspeakers 108 and 116 on the other hand.

Each of the distributed mode loudspeaker channels 124 comprises a digital volume control, seven band equaliser with pre-sets and power amplifier similar to the components 66, 68, 68a, 70 as described reference to FIG. 14. Each of the cone loudspeaker channels 126 and 128 comprises the conventional circuitry for driving conventional cone loudspeakers such as the usual filters, volume control (in this case digitally controlled), power amplifier and graphic equaliser if appropriate or desired.

The conventional controls 136 control the four channels 124, 126, 128, 130 to produce the required outputs in accordance with the settings of the conventional controls 138 (volume, filtering, equalisation etc.). The relative volume control 140 adjusts the relative power levels of signals supplied to the terminals 102 and 110 on the one hand and the terminals 104 and 112 on the other hand so that the volume or sound pressure levels produced by the distributed mode loudspeakers 106 and 114 can be adjusted relative to the volumes or sound pressure levels produced by the conventional cone loudspeakers 108 and 106, preferably to enable the output of the distributed mode loudspeakers to be set at −5 decibels+/−3 decibels relative to the output of the conventional cone loudspeakers as previously explained above and also to provide the other possible settings to take into account user preference and room acoustics and the characteristics of the loudspeakers used.

Thus, in accordance with this embodiment, a novel stereophonic amplifier is provided having first and second left channels and first and second right channels for simple connection to distributed mode and cone loudspeakers as described, thereby to implement the invention.

### Seventh Embodiment

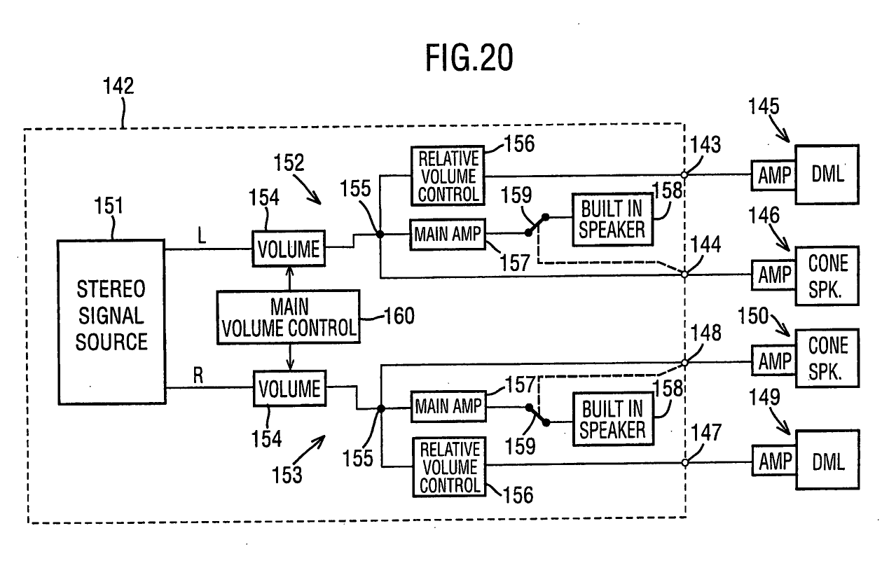

FIG. 20 is a block diagram of another embodiment of the invention which comprises a self-contained sound reproduction apparatus 142. The self-contained apparatus 142 has first and second left line level connector sockets 143 and 144 for connection respectively to an active distributed mode loudspeaker 145 and an active conventional cone loudspeaker 146 and first and second right line level connector sockets 147 and 148 for connection respectively to an active distributed mode loudspeaker 149 and an active conventional cone loudspeaker 150. The word “active” in relation to the loudspeakers means, as is conventional and as is illustrated in the drawings, that the loudspeakers are provided with built-in power amplifiers, thereby enabling them to reproduce sound from a line level signal.

The self-contained reproduction apparatus 142 includes one or more stereo signal sources 151, for example an FM radio tuner and/or compact disc player, having left and right outputs supplied to left and right channels 152 and 153 respectively. Each of these channels comprises a volume control 154 having an output terminal 155 which is connected to the input of a relative volume control circuit 156, the input of a main power amplifier 157 and, in the case of the left channel, to the output socket 144 and, in the case of the right channel, to the output socket 148. Left and right built-in conventional cone loudspeakers 158 are included in the apparatus 142 and connected to the outputs of the respective power amplifiers 157 through respective switches 159. The connectors 143, 144, 147, 148 are preferably standard sockets for receiving standard plugs. A mechanical connection is provided between the sockets 144 and 148 to the respective switches 159 so that these switches are opened to disconnect the built-in speakers when plugs (not shown) are inserted into these sockets.

A main volume control device 160, which is user operated, controls the main volume control circuits 154 of the two channels simultaneously. User operated control elements such as knobs are provided for adjusting the relative volume control circuits 156 so as to adjust the outputs of the distributed mode loudspeakers relative to the outputs of the cone loudspeakers. In this embodiment, it is assumed that each of the two relative volume control circuits has its own individual user operated control element so that the relative volumes of the distributed mode and cone loudspeakers in the left and right channels respectively can be individually adjusted. If desired, the circuit may be modified so that a single relative volume control element is provided for actuation by the user to simultaneously adjust the relative volumes of the left and right channels.

Preferably the frequency ranges reproduced by the loudspeakers 145, 146, 149 and 150 are as previously described for the distributed mode and conventional cone loudspeakers and the relative volumes can be adjusted as previously described at various parts of this specification.

As will be apparent from the description of FIG. 20, the distributed mode loudspeakers 145 and 149 can be used either in combination with the external cone loudspeakers 146 and 149 or with the built-in loudspeakers 158.

The self-contained sound reproduction apparatus 142 may be in the form of a portable device such as a portable radio or portable CD player or portable radio/CD player or it may be, for example, the sound system of a television receiver or of a computer such as a portable computer.

### Eighth Embodiment

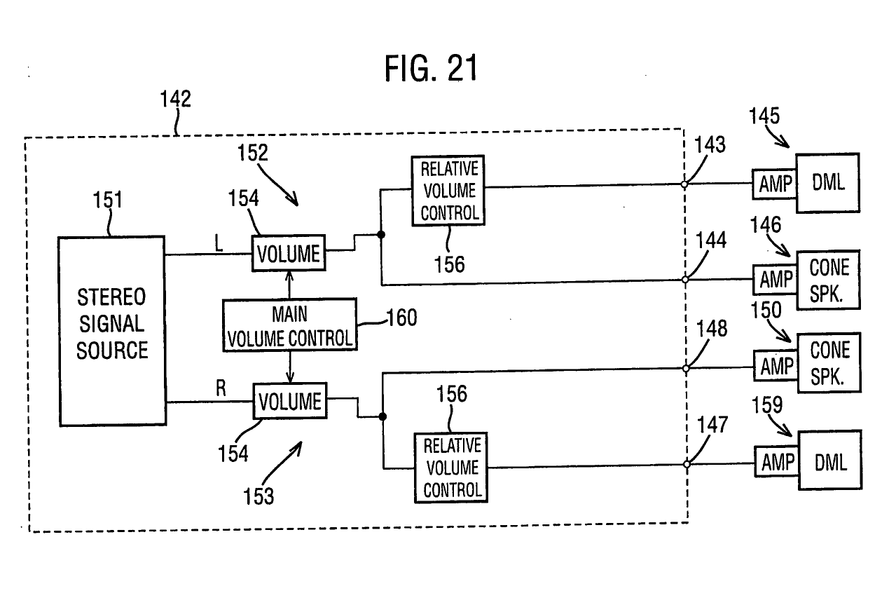

The embodiment of FIG. 21 is identical to that of FIG. 20 except that the built-in loudspeakers 158, main amplifiers 157 and switches 159 (and the associated mechanical links to the sockets 144 and 148) are omitted.

### Ninth Embodiment

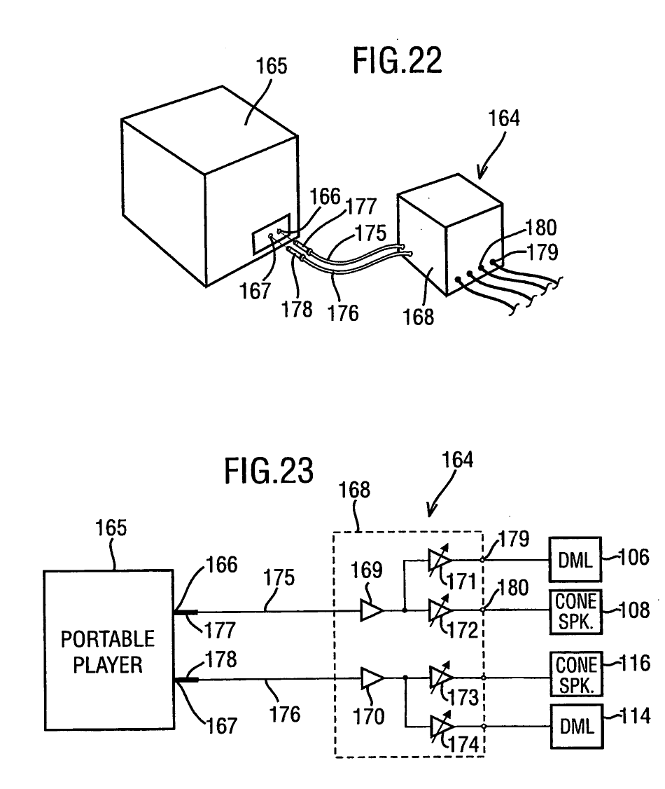

FIGS. 22 and 23 show an embodiment of the invention which comprises left distributed mode and conventional cone loudspeakers and right distributed mode and conventional cone loudspeakers 106, 108, 114 and 116 as described with reference to FIG. 18 driven via an amplifier unit 164 by a conventional portable player 165, such as a CD player or tape player, having left and right channel line level outputs 166 and 167 respectively.

The amplifier unit comprises a housing 168 containing left and right channel buffer amplifiers 169, 170, first and second left channel power amplifiers 171, 172 and first and second right channel power amplifiers 173 and 174. Left and right channel input leads 175 and 176 are connected by conventional plugs 177, 178 to the line level outputs 166 and 167 respectively to supply the left and right line level signals produced by the portable player 165 to the inputs of the buffer amplifiers 169 and 170 respectively. The left channel power amplifiers 171, 172 independently amplify the signal produced by the buffer amplifier 169 for driving the distributed mode loudspeaker 106 and the conventional cone loudspeaker 108 respectively via terminals 179 and 180. Similarly, the right channel power amplifiers 173 and 174 amplify the signal supplied by the buffer amplifier 170 for driving right distributed mode loudspeaker 114 and the right conventional cone loudspeaker 116 via terminals 181 and 182 respectively.

The four power amplifiers 171, 172, 173, 174 include respective volume control circuits to enable the outputs of the four loudspeakers to be individually adjusted. The frequency ranges over which the distributed mode and conventional cone loudspeakers in this embodiment operate are as previously described and the differences in sound pressure output between the distributed mode loudspeakers and conventional cone loudspeakers are also adjustable within the ranges previously described.

The amplifier unit 164 accordingly makes it possible to implement the invention using a conventional stereo player having line level outputs by adding two conventional cone loudspeakers and two distributed mode loudspeakers external to the conventional stereo player. The amplifier unit may be made and sold separately from the other components. It may be sold with or without connecting leads.

The individual plugs 177 and 178 illustrated in FIGS. 22 and 23 may, in a modification, be replaced by standard stereo plugs such as a “mini-plug” when the player is provided with the kind of conventional socket which receives such a plug.

### Tenth Embodiment

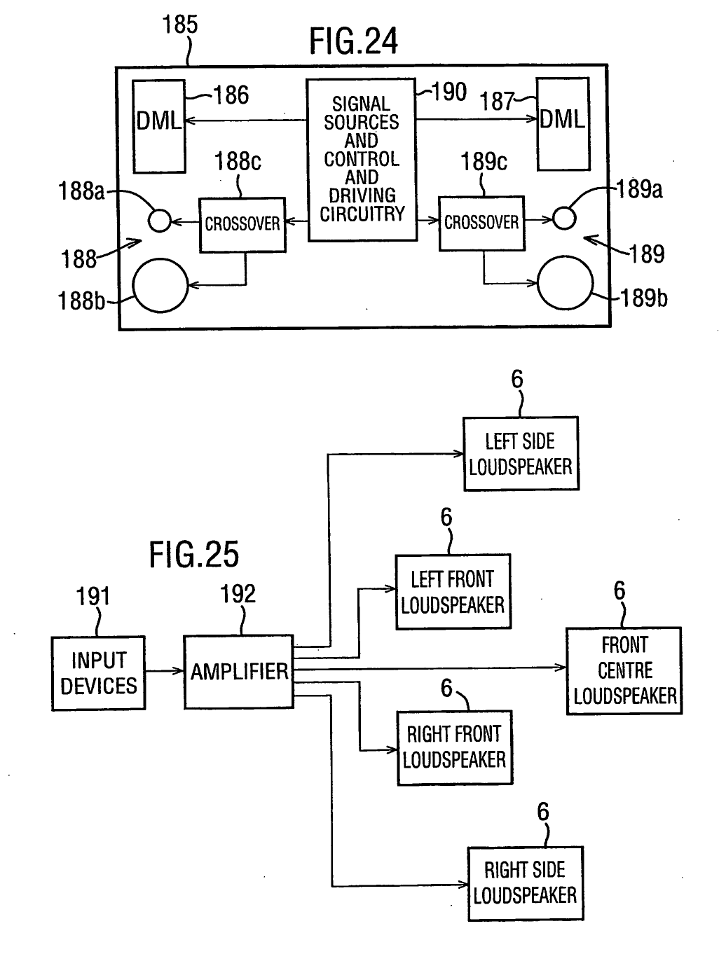

FIG. 24 illustrates another embodiment of the invention which is in the form of a self-contained sound reproduction apparatus. This comprises a housing represented diagrammatically at 185 which contains all the components necessary for implementation of the invention. Thus, the housing 185 contains left and right distributed mode loudspeakers 186, 187 and left and right two-way conventional cone loudspeaker systems 188 and 189 comprising respectively tweeters 188a and 189a, woofers 188b and 189b and conventional crossover circuits 188c and 189c. One or more stereo signal sources together with the required control and loudspeaker driving circuitry are generally indicated by reference number 190 and are also contained in the housing 185 and is provided with the usual user actuated controls, such as volume, balance, treble and bass controls. The signal channels for driving and controlling the distributed mode loudspeakers and the conventional cone loudspeakers may be as previously described and may thus include both an overall volume control and a relative volume control for adjusting the volume levels of the distributed mode and conventional loudspeakers relative to each other.

As in the previous embodiment, the frequency range produced by the distributed mode loudspeakers substantially overlaps, or preferably is substantially the same as, the frequency range produced by the conventional cone loudspeakers although in the case of a self-contained portable device the frequency range may be less than in the case of a high fidelity system for use, for example, in the home. The self-contained device 185 may take any of a variety of different forms, such as a portable radio and/or CD and/or tape player, a television receiver or a portable computer. Where the invention is embodied in a computer, some or all the controls may be implemented in software.

### Eleventh Embodiment

The invention may be used in so-called “surround sound” systems. FIG. 25 shows an example of such an implementation.

With reference to FIG. 25, conventional surround sound input devices 191 are connected to a conventional surround sound amplifier 192 having five channels, namely left, centre and right front channels and left and right side channels each connected to a respective different loudspeaker 6 which will be positioned in the appropriate places in listening room. The loudspeakers 6, each as described in detail with reference to FIGS. 9 to 13, thereby implementing the invention in a surround sound system.

### Embodiments of the Invention in Digital Pianos

It is well known that even the best quality digital pianos which are currently available produce a sound which is relatively unmusical. Embodying the teachings of the present invention in digital pianos makes it possible to provide a much more realistic musical sound from a digital pianos. Specifically, digital pianos according to the invention may produce highly enriched sounds with random components which, provided the piano is constructed to an adequate quality, give to the listener the impression that the sounds produced are close in quality to the sounds of a high-quality acoustic grand piano. This may be achieved at much lower cost than that of a top-quality acoustic piano.

Grand Piano

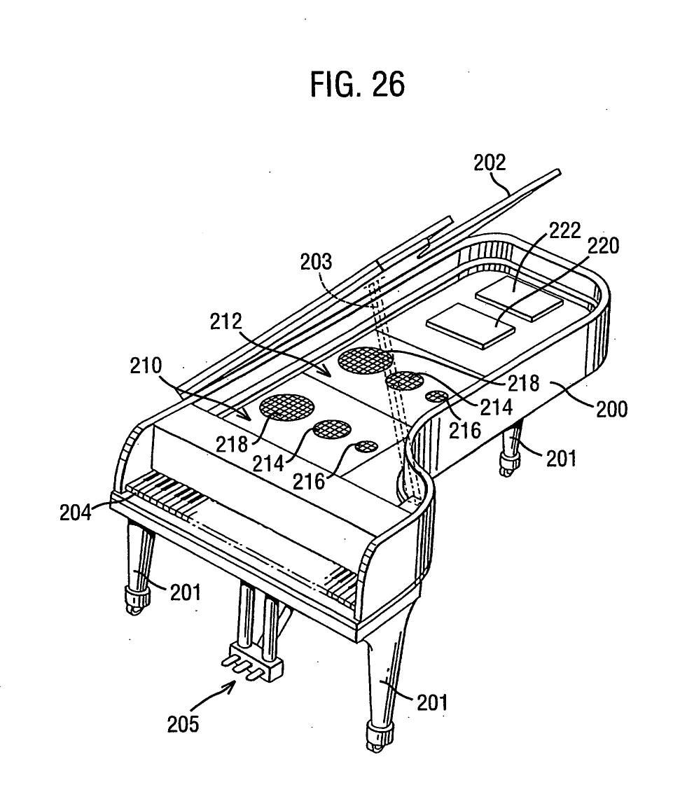

FIG. 26 shows in perspective view a digital grand piano according to an embodiment of the invention. The piano comprises a casing 200 supported on legs 201 and having a conventional hinged lid 202 shown supported in the open position by a conventional stay 203. A keyboard 204 of the kind conventionally used in digital pianos and a set of pedals 205 performing the normal functions are supported in the usual positions by the casing 200. The piano preferably includes (as is already known in the art of digital pianos) a conventional high-quality grand piano action (not shown) connected to the keyboard for the purpose of providing the player with the feel of a good-quality concert grand.

The casing 4 supports two loudspeaker assemblies 210 and 212, each comprising a tweeter 216, a mid-range unit 214 and a sub-woofer 218, arranged respectively in alignment with the treble, mid-range and base portions of the keyboard. Each of the loudspeakers 216, 214 and 218 is a conventional electro-magnetically driven cone loudspeaker arranged so that the cones face vertically upwardly and the sounds produced thereby are reflected by the lid of the piano. Although this orientation is particularly preferred for the tweeter and mid-range loudspeakers, the orientation of the sub-woofers is not particularly significant.

The casing 4 also supports two distributed mode loudspeakers 220 and 222 which are positioned horizontally so as to radiate sound upwardly and downwardly. By way of example, the panels of the distributed mode loudspeakers 220, 222 might measure 700×500 mm each.

It should be understood that the positioning of the loudspeakers shown in FIG. 26, with the conventional loudspeakers grouped near to the keyboard and the distributed mode loudspeakers remote from the keyboard, is merely exemplary. The conventional and distributed mode loudspeakers may alternatively be interleaved with each other or the positions reversed relative to that shown in the drawing. Also, the tweeters, mid-range units and sub-woofers of the conventional loudspeaker assemblies may be separated and interleaved with the distributed mode loudspeakers.

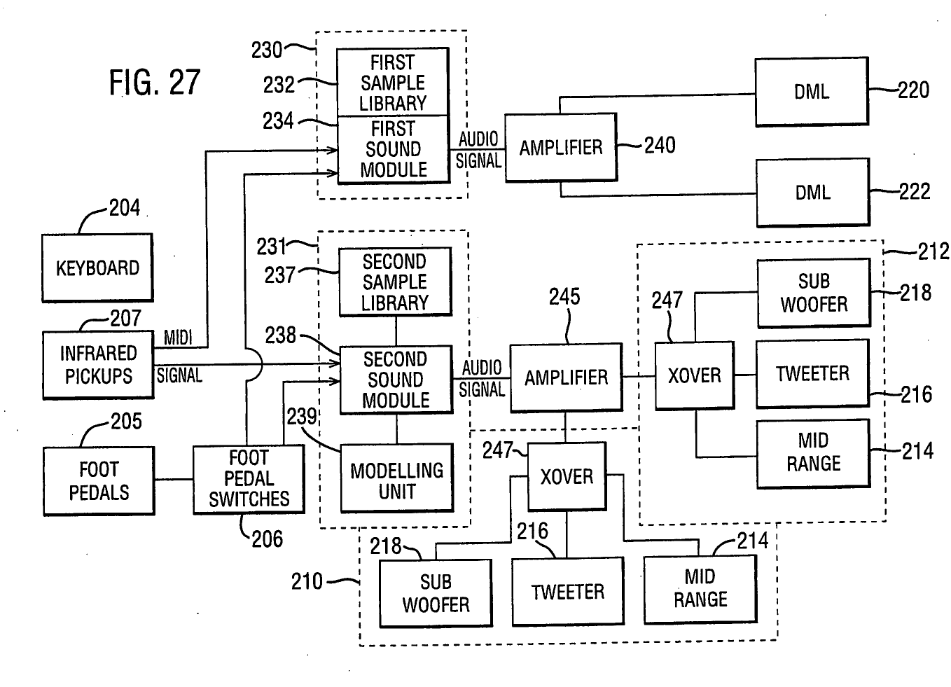

As shown in FIG. 27, signals from foot pedal switches 206 and a midi signal generated in response to signals from infrared pickups 207 (not shown in FIG. 26) arranged beneath the keyboard 204 of the piano are passed to a first audio signal generator 230 and a second audio signal generator 231 both arranged to respond to the MIDI signals and the foot pedal switches 107 for generating audio signals replicating the sound of a grand piano. The first and second generation 230, 231 may be implemented by means of a conventional computer containing known software for this purpose.

The first audio signal generator 230 in this embodiment comprises a first high quality sample library 232 and a first sound module 234. The second audio signal generator comprises a second high quality sample library 237, a second sound module 238 and a physical modelling unit 239. The respective libraries 232 and 237 comprise digital samples recorded from different high quality grand pianos preferably concert grands. Thus for example the first sound sample library 232 might comprise a 1.6 Gb Steinway sample library and the second sample library 237 might comprise a Yamaha 30 Mb sample sound library. The sound modules 234, 238 comprise software programs for selecting sound samples from the sound libraries 232, 237 in response to received MIDI signals and signals from the foot pedal switches 107. As the second sample library 237 is (in this embodiment) significantly smaller than the first sample library 232, the second audio signal generator 231 also includes a physical modelling unit 239 arranged to modify, in a conventional manner, the sound samples selected by the second sound module 238.

The audio signal from the generator 230 is amplified by an amplifier 240 and the amplified signal drives the two to the two distributed mode loudspeaker 220, 222.

The audio signal from the generator 231 is amplified by an amplifier 245 and supplied to crossover units 247 to drive the two conventional speakers 210, 212. The crossover units 247, in a conventional manner, pass high frequency, mid range and low frequency signals to the tweeter 216, woofer 214 and base 218 of the conventional speakers 210, 212 respectively.

The cone loudspeakers reproduce sound over substantially the whole of the audio frequency range, say from 20 Hz to 20 kHz or from 45 Hz to 20 KHz. The distributed mode loudspeakers produce sound over as much of that range as practical, say 80 Hz to 20 KHz or 100 Hz to 20 kHz. The sound pressure levels provided by the distributed mode loudspeakers may be adjusted to be less than those produced by the conventional cone loudspeakers, again as previously described or dependent upon the acoustics of the auditorium or room in which the piano is played, or the output of the distributed mode loudspeakers may have substantially the same sound pressure level or even higher sound pressure level than that of the conventional cone loudspeakers. To enable the sound pressure levels of the distributed mode loudspeakers to be varied independently of the sound pressure levels of the conventional cone loudspeakers, independent volume controls for the distributed mode and cone loudspeakers are preferably provided although these are not shown in the drawings.

When the piano is played, the distributed mode loudspeakers and the conventional loudspeakers are driven simultaneously. As a result, the different air disturbance patterns which are propagated respectively by the distributed mode loudspeakers and conventional cone loudspeakers combine to produce air disturbance patterns having a complexity and richness, arising from randomly varying interactions between the different patterns, to provide a substantially richer sound than could be produced by either type of loudspeaker individually. This richness is further enhanced in that the signals used for driving the distributed mode loudspeakers differ from those used for driving the conventional loudspeakers.

Furthermore, as explained with reference to the above described experiments, improvements in spaciousness are achieved by the combination of distributed mode and conventional cone loudspeakers.

Although in this embodiment samples from two different models of grand piano are employed, further richness may be achieved by utilising samples from three or more different grand pianos in which case different ones of the loudspeakers might be driven by signals derived from respective different sets of samples. Further, samples other than Steinway and Yamaha samples may be used and the sound libraries which are employed may be, and for the highest quality instruments preferably are, such that they both contain the maximum number of samples available having regard to the current state-of-the-art. More specifically, as computer memory increases in capacity and reduces in cost, it is possible to provide sound libraries containing more and more samples and therefore possibilities for better and better quality of sound.

Digital Upright Piano

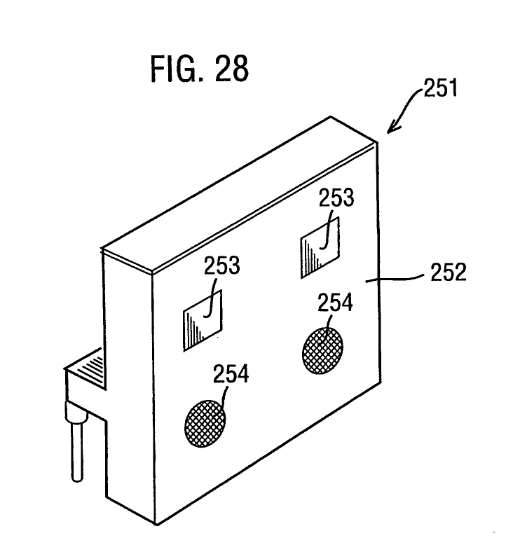

With reference to FIG. 28, digital upright piano, which may produce a sound of lower quality than that produced by the piano of FIGS. 26 and 27 but which may be of lower cost, comprises a casing 251 having back panel 252 supporting a pair of distributed mode loudspeakers 253 and also a pair of conventional cone loudspeakers 254. In this embodiment in contrast to the previous embodiment only two cone loudspeakers are provided, in order to reduce cost. The distributed mode loudspeakers 253 are provided oriented parallel to the plane of the back panel 252 of the casing 251. The cones of the two conventional speakers 254 are oriented with the axis of the cone perpendicular to the plane of the back panel 252.

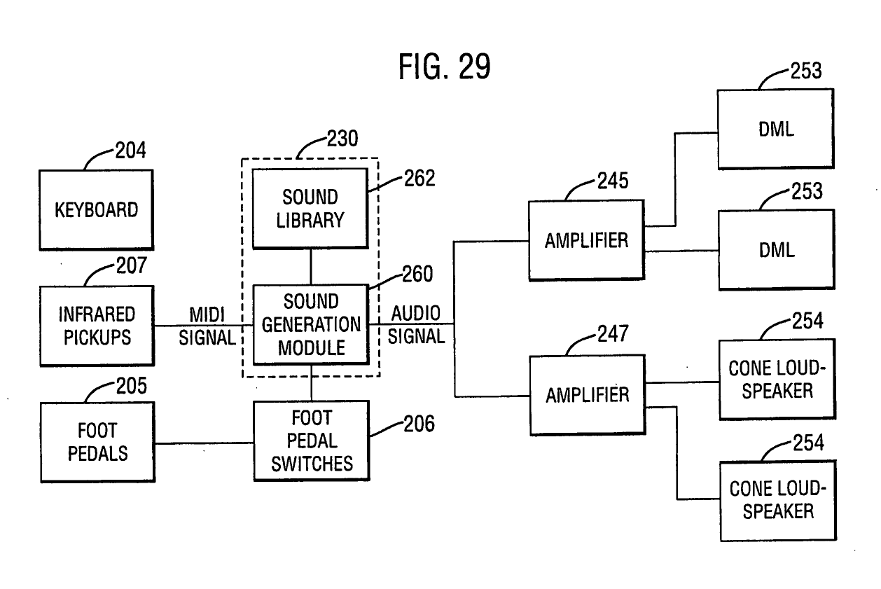

FIG. 29 is a schematic block diagram of the piano of FIG. 28. In contrast to the previous embodiment, only a single audio signal generator 230, comprising a sound library 262 and a sound generation module 260, is provided to save costs. The generator 230 generates an audio signal using the sound library 262 on the basis of the received signals from the infrared pickups 207 and foot pedal switches 207.

As in the previous embodiment the distributed mode loudspeakers 253 and conventional cone loudspeakers 254 are arranged so as to be driven simultaneously through amplifiers 245, 247 so that the electronic piano is caused to create an air disturbance pattern which is the combination of sound output by the distributed mode loudspeaker 253 and the conventional loudspeakers 254, thereby more closely emulating the propagation of sound generated by an acoustic instrument as explained above. Further, although, as is clear from FIG. 29, no crossover circuits are included since it is assumed that the two cone loudspeakers 254 are identical and thus have a relatively restricted frequency range, the frequency range of the distributed mode loudspeakers should overlap the frequency range of the conventional cone loudspeakers as far as possible to enhance spaciousness of the sound as discussed above in connection with the experiments. However, it will not be possible for the quality of the sound produced by the embodiment of FIGS. 28 and 29 to be as good as that produced the in the embodiment of FIGS. 26 and 27 although, with appropriate quality of components, even the embodiment of FIGS. 28 and 29 should be capable of achieving greater overall quality than many currently available digital pianos.

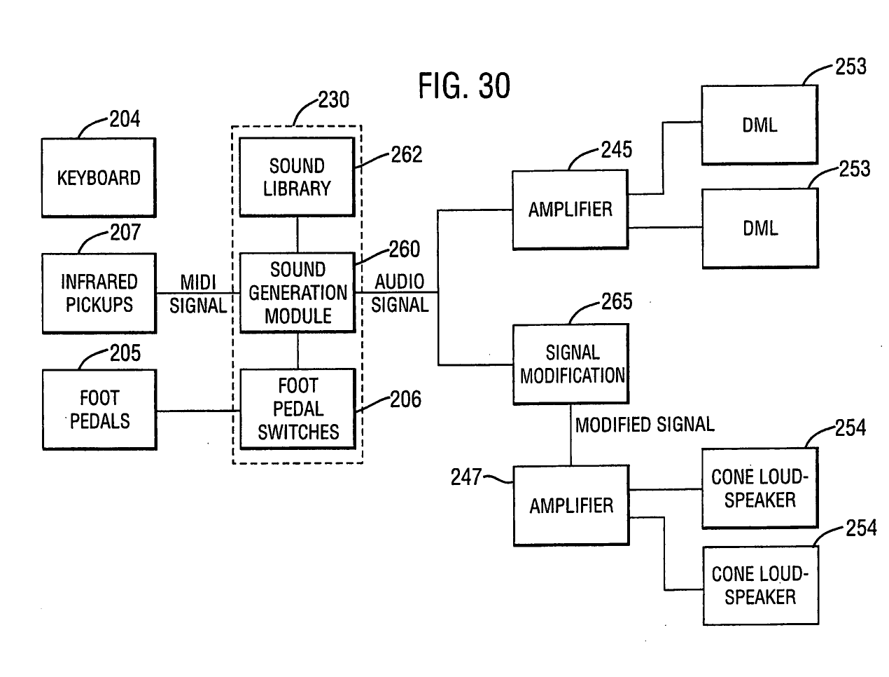

With a view to providing some further improvement, a modification to the circuit of FIG. 29 is shown in FIG. 30. In this, the audio signal generated by the generator 230 260 is passed to a signal modification unit 265 such as a digital signal processing unit, which generates a modified signal that is passed to the amplifier 247 which drives the cone loudspeakers 254. The signal modification unit 265 may be arranged to alter the timing and timbre of the audio signal output by the sound generation unit 260. This signal modification unit 265 includes a conventional user interface (not shown) which enables a user to select the manner in which signals output by the sound generation unit 260 are modified. In this way, the richness of the sound may be enhanced to some degree because the qualities of the signal which drive the cone loudspeakers differ slightly from the qualities of the signal which drive the distributed mode loudspeakers. If desired, a further signal modification unit could be interposed between the sound generation module 260 and the amplifier 245 which drives the distributed mode loudspeakers to introduce further richness.

Although in the previous three embodiments, sound has been described as being output through pairs of distributed mode loudspeakers and pairs of conventional loudspeakers, it will be appreciated that a similar random mixing of air disturbance patterns could be achieved by outputting sound simultaneously corresponding to the same notes through a single distributed mode loudspeaker and a single cone loudspeaker.

Although in previous embodiments an infrared motion detection system for detecting the motion of keys has been described utilizing infrared motion detection, other means may be used to detect the depression keys for example an electromechanical motion detection system could be used to detect the position, pressure and velocity of key activation.

Auxiliary Unit for Digital Piano

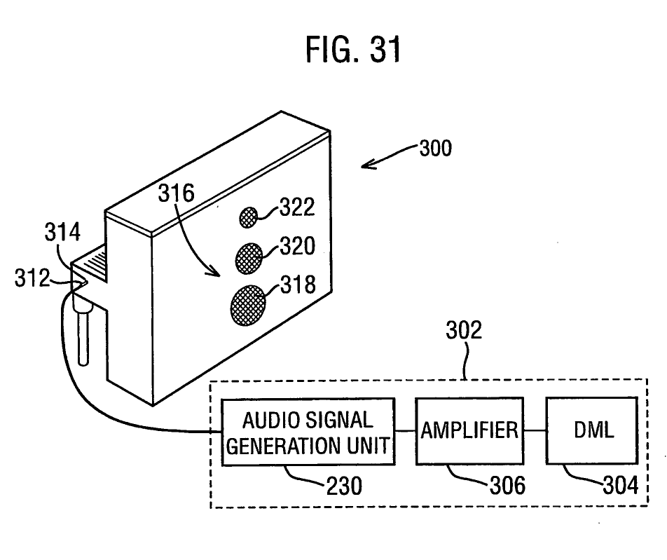

Many people already own digital pianos. FIG. 31 illustrates a conventional digital piano of 300 connected to an auxiliary unit 302 to form a piano which embodies the present invention.

As seen in FIG. 4, the auxiliary unit 302 comprises a distributed mode loudspeaker 304 driven by an amplifier 306 which receives signals from an audio signal generator (which is as previously described) connected via a cable 310 and a plug 312 to the MIDI signal output 314 conventionally provided on currently available digital pianos.

The conventional digital piano 300 includes a three-way conventional cone loudspeaker system 316 comprising a woofer 318, a mid-range unit 320 and a tweeter 322 driven through conventional crossover circuits (not shown) and thereby operable to produce substantially the full audio frequency range of from, say, 20 Hz to 20 kHz. The distributed mode loudspeaker 304 is operable to produce frequencies over a substantial part of the frequency range produced by the loudspeaker system 316, for example 100 Hz to 20 kHz.

Although not shown in FIG. 31, the conventional digital piano 300 operates using a sound library of samples recorded from, typically, a good-quality concert grand. The audio signal generator 230 also contains a sound library preferably containing samples recorded from a different model of good-quality concert grand, for the reasons explained in relation to the embodiment of FIGS. 26 and 27.

The auxiliary unit 302 may be made and sold separately from digital pianos so that it may be connected to an existing digital piano owned by the purchaser. By simply connecting the auxiliary unit 302 to the existing MIDI output of the digital piano and ensuring that the volume control of the digital piano is set at a level so that sound is produced by the conventional speaker system 316 in addition to sound being produced by the distributed mode loudspeaker 304, the benefits of the invention can be achieved.

Variations and Modifications

As can be seen from the above description, the invention can be embodied in a wide variety of different ways. Many further modifications of variations in those described above are possible within the scope of the invention.

For example, the invention may be embodied in public address systems, sound systems in theatres and cinemas, in-car entertainment systems or monitoring systems in recording or broadcasting studios.

In addition to digital pianos, the invention may be employed for reproducing sound from other electrical or electronic musical instruments, such as electric guitars.

Although in each of the above described and illustrated embodiments, conventional cone loudspeakers have been employed it is possible instead to use, at least in certain circumstances, alternative forms of pistonic loudspeaker, such as an electrostatic loudspeaker or a piezo electric loudspeaker comprising a flat panel or membrane mounted for vibratory motion and driven by a piezo electric transducer. However, in most circumstances electromagnetically driven cone loudspeakers will be preferred.

Although in all of the sound reproduction apparatus embodiments of FIGS. 8 to 24, stereophonic apparatus has been illustrated any of these embodiments could be modified to single channel, mono apparatus. As already explained, the effects of the invention are achieved also in mono applications.

The introduction of a delay in the signal applied to the distributed mode loudspeakers relative to the signal applied to the pistonic loudspeakers has been discussed above. This may be provided in any of the embodiments described with reference to the drawings and in any other embodiments. Preferably, where a delay is provided, this will be adjustable by the user to suit the circumstances in which the invention is to be deployed.

Further, additional similar processing of the signals applied to the distributed mode and/or pistonic loudspeakers could be provided, for example to provide reverberation, equalisation, or other effects.

Various preferred frequency ranges and relative output levels have been given in the description of a number of the above embodiments. It should be understood that these are examples only and that many variations are possible. It is, however, important that the frequency range of the distributed mode loudspeaker or loudspeakers should overlap the frequency range of the pistonic loudspeaker or loudspeakers. Further, although in many instances, particularly in sound reproduction systems embodying the invention, optimum results will be achieved by arranging for the sound pressure level of the distributed mode loudspeaker to be slightly less than that of the cone loudspeakers, e.g. just a few decibels difference, improvements are achieved where the distributed mode loudspeaker produces a substantially lower sound pressure level than the cone loudspeakers provided, of course, that the pressure level of the distributed mode loudspeakers is not so low that the sound produced thereby is imperceptible. In the experiments, distributed mode loudspeaker sound pressure levels of as low as −35 decibels relative to the cone loudspeakers have still achieved perceptible, but at this level only marginal, improvement.

In certain situations it may be desirable for the sound pressure level produced by the distributed mode loudspeakers to be greater than that produced by the pistonic loudspeakers.

Although in the embodiments described with reference to the drawings, the distributed mode loudspeaker and the pistonic loudspeaker have been illustrated as separate devices, it is within the scope of the invention to use a loudspeaker having an element, such as a panel, which is both movable in a pistonic mode of operation and is excitable into distributed mode operation so that the same element constitutes both part of the pistonic loudspeaker and part of the distributed mode loudspeaker. In this case, a suitable transducer arrangement would be provided for causing the element to operate in both modes; for example a first transducer could be provided for causing the element to move pistonically and a second transducer provided for exciting the element into distributed mode operation.

I claim:

1. A sound generation process utilizing a loudspeaker arrangement comprising distributed mode and pistonic loudspeaker devices, said arrangement being such that each said loudspeaker device generates sound with a frequency response which, measured under anechoic conditions, comprises an operating range and roll-off portions respectively above and below the upper and lower ends of the operating range, said operating ranges of said distributed mode and said pistonic loudspeaker devices overlapping without roll-off over at least one octave in the frequency band up to 6 kHz, said distributed mode and pistonic loudspeaker devices being driven simultaneously from a common audio signal so that both said loudspeaker devices produce the sounds represented by said common audio signal at least over said at least one octave.

2. A process according to claim 1, wherein said operating ranges overlap at least over a plurality of octaves in the frequency band up to 6 kHz and said distributed mode and pistonic loudspeaker devices produce the sounds represented by said common audio signal at least over said plurality of octaves.

3. A process according to claim 1, wherein said operating ranges overlap over a plurality of octave bands selected from the group comprising the 125 Hz, 250 Hz, 500 Hz, 1 kHz, 2 kHz, and 4 kHz octave bands; and said distributed mode and pistonic loudspeaker devices produce the sounds represented by said common audio signal at least over said overlapping plurality of octave bands.

4. A process according to claim 1, wherein said operating ranges of said distributed mode and pistonic loudspeaker devices extend over substantially the same frequency range.

5. A process according to claim 1, wherein said operating range of said distributed mode loudspeaker device extends over a narrower frequency range than said operating range of said pistonic loudspeaker device.

6. A process according to claim 1, wherein the sound pressure level, at a position within a space suitable for listening, produced by the distributed mode loudspeaker device is less than that produced by the pistonic loudspeaker device.

7. A process according to claim 6, wherein the sound pressure level, at a position within a space suitable for listening, produced by the distributed mode loudspeaker device is less than that produced by the pistonic loudspeaker device by 5+/−3 decibels.

8. A process according to claim 1, which includes the step of adjusting the relative sound pressure levels produced by said distributed mode and pistonic loudspeakers.

9. A process according to claim 1, wherein the sound produced by the distributed mode loudspeaker device is delayed relative to that produced by the pistonic loudspeaker device.

10. A process according to claim 9, in which the delay is not more than 80 msecs.

11. A process according to claim 9, in which the delay is not more than 35 msecs.

12. A process according to claim 1 performed in a single channel for producing mono sound.

13. A process according to claim 1, performed simultaneously in first and second channels for reproducing stereophonic sound.

14. A process according to claim 1, performed simultaneously in each of a plurality of channels of a surround sound system.

15. A process according to claim 1 performed in a vehicle.

16. A process according to claim 1 performed in a domestic environment.

17. A process according to claim 1, wherein sound from said arrangement is received at a listening position in a listening space both directly from the arrangement and after reflection from a sound reflective surface.

18. A process according to claim 17, wherein said listening position is within a listening space having a boundary and said reflective surface comprises at least a portion of said boundary.

19. A loudspeaker assembly comprising a distributed mode loudspeaker and a pistonic loudspeaker, and a circuit having a common input terminal for driving both said loudspeakers simultaneously from a common input signal representing the sound to be reproduced, said assembly being such that each said loudspeaker is operable to generate sound with a frequency response which, measured under anechoic conditions, comprises an operating range and roll-off portions respectively above and below the upper and lower ends of the operating range, said operating ranges of said distributed mode and said pistonic loudspeakers overlapping without roll-off over at least one octave in the frequency band up to 6 kHz.

20. An assembly according to claim 19, wherein said operating ranges overlap at least over a plurality of octaves in the frequency band up to 6 kHz.

21. An assembly according to claim 19, wherein said operating ranges overlap a plurality of octave bands selected from the group comprising the 125 Hz, 250 Hz, 500 Hz, 1 kHz, 2 kHz, and 4 kHz octave bands; and said distributed mode and pistonic loudspeakers produce the sounds represented by said common audio signal at least over said overlapping plurality of octave bands.

22. An assembly according to claim 19, wherein said operating ranges of said distributed mode and pistonic loudspeakers extend over substantially the same frequency range.

23. An assembly according to claim 19, wherein said operating range of said distributed mode loudspeaker extends over a narrower frequency range than said operating range of said pistonic loudspeaker.

24. An assembly according to claim 19, wherein said circuit includes an attenuator for attenuating driving signals applied to the distributed mode loudspeaker relative to driving signals applied to the pistonic loudspeaker.

25. An assembly according to claim 19, including a volume control for adjusting the relative sound pressure levels of the distributed mode loudspeaker and the pistonic loudspeaker.

26. An assembly according to claim 19, including a delay device for introducing a delay between the output of the pistonic loudspeaker and the distributed loudspeaker.

27. An assembly according to claim 26, wherein said delay device is operable to introduce a delay to the sound produced by the distributed mode loudspeaker relative to that produced by the pistonic loudspeaker.

28. An assembly according to claim 19, wherein said circuit includes a signal conditioner for modifying signals applied to said distributed mode loudspeaker.

29. An assembly according to any of claims 21, wherein said circuit includes first and second amplifiers having outputs coupled respectively to said distributed mode loudspeaker and said pistonic loudspeaker and inputs coupled to said common input terminal, for enabling said assembly to produce sound from a line level input.

30. An assembly according to claim 19, including a common support structure supporting said distributed mode loudspeaker and said pistonic loudspeaker.

31. An assembly according to claim 30, wherein said common support structure is a housing and said housing contains both said distributed mode loudspeaker and said pistonic loudspeaker.

32. Sound production apparatus comprising a distributed mode and a pistonic loudspeaker and an amplifier for driving said loudspeakers, the arrangement being such that:
(a) each said loudspeaker is operable to generate sound with a frequency response which, measured under anechoic conditions, comprises an operating range and roll-off portions respectively above and below the upper and lower ends of the operating range, said operating ranges of said frequency responses overlapping without roll-off over at least one octave in the frequency band up to 6 kHz, and
(b) said amplifier is operable to drive said distributed mode and said pistonic loudspeakers simultaneously from a common audio signal so that said distributed mode and pistonic loudspeakers both produce the sounds represented by said common audio signal at least over said at least one octave.

33. Apparatus according to claim 32, wherein the arrangement is such that said operating ranges overlap over a plurality of octaves in the frequency band up to 6 kHz and such that said distributed mode and pistonic loudspeakers may both produce the sounds represented by said common audio signal at least over said plurality of octaves.

34. Apparatus according to claim 32, wherein said operating ranges overlap a plurality of octave bands selected from the group comprising the 125 Hz, 250 Hz, 500 Hz, 1 kHz, 2 kHz, and 4 kHz octave bands; and said distributed mode and pistonic loudspeakers produce the sounds represented by said common audio signal at least over said overlapping plurality of octave bands.

35. Apparatus according to claim 32, wherein the arrangement is such that said operating ranges of said distributed mode and pistonic loudspeakers extend over substantially the same frequency range.

36. Apparatus according to claim 32, wherein the arrangement is such that the distributed mode loudspeaker device operates over a narrower frequency range than said operating range of said pistonic loudspeaker device.

37. Apparatus according to claim 32, adapted to operate such that the sound pressure level produced by the distributed mode loudspeaker device at a position in a listening space is less than that produced by the pistonic loudspeaker device.

38. Apparatus according to claim 37, adapted to operate such that the sound pressure level produced by the distributed mode loudspeaker device at a position in a listening space is less than that produced by the pistonic loudspeaker device by 5+/−3 decibels.

39. Apparatus according to claim 32, including a volume control operable for adjusting the relative sound pressure levels of the distributed mode and the pistonic loudspeakers.

40. Apparatus according to 32, including a delay device for introducing a delay between the output of the pistonic and distributed loudspeakers.

41. Apparatus according to claim 40, wherein said delay device is operable for introducing a delay to the sound produced by the distributed mode loudspeaker relative to that produced by the pistonic loudspeaker.

42. Apparatus according to claim 41, wherein said delay device is operable such that said delay is less than 80 msecs.

43. Apparatus according to claim 41, wherein said delay device is operable such that said delay is less than 35 msecs.

44. Apparatus according to any of claims 32, which includes a signal conditioner for modifying the signals applied to said distributed mode loudspeaker.

45. Apparatus according to claim 32, comprising a first said amplifier for driving the distributed mode loudspeaker and a second said amplifier for driving the pistonic loudspeaker.

46. Apparatus according to claim 32, which comprises a single channel and is adapted for producing monophonic sound.

47. Apparatus according to claim 32, adapted for producing stereophonic sound and including
(a) a first said distributed mode loudspeaker and a first said pistonic loudspeaker for left channel reproduction, and
(b) a second said distributed mode loudspeaker and a second said pistonic loudspeaker for right channel reproduction, said amplifier having a left channel for driving said first distributed mode and said first pistonic loudspeaker from a common left audio signal and a right channel for driving said second distributed mode loudspeaker and said second pistonic loudspeaker from a common right audio signal.

48. Apparatus according to claim 47, wherein said left channel comprises first and second left sub-channels for respectively driving said left distributed mode loudspeaker and said left pistonic loudspeaker from said common left audio signal, and first and second right sub-channels for respectively driving said right distributed mode loudspeaker and said right pistonic loudspeaker from said common right audio signal.

49. Apparatus according to claim 32, wherein said amplifier comprises multiple channels for producing multiple channel surround sound, and comprising, for each channel thereof, a respective said distributed mode loudspeaker and pistonic loudspeaker.

50. Apparatus according to claim 32, including a common support structure supporting said distributed mode loudspeaker and said pistonic loudspeaker.

51. Apparatus according to claim 50, wherein said common support structure is a housing and said housing contains both said distributed mode loudspeaker and said pistonic loudspeaker.

52. Apparatus according to claim 47, comprising a first common support structure supporting said first distributed mode loudspeaker and said first pistonic loudspeaker; and a second common support structure supporting said second distributed mode loudspeaker and said second pistonic loudspeaker.

53. Apparatus according to claim 47, comprising a first common housing containing said first distributed mode loudspeaker and said first pistonic loudspeakers; and a second common housing containing said second distributed mode loudspeaker and said second pistonic loudspeaker.

54. Apparatus according to claim 49, comprising a plurality of common support structures each corresponding to a respective different one of said plurality of channels, each common support structure supporting both the distributed mode loudspeaker and the pistonic loudspeaker of said corresponding channel.

55. Apparatus according to claim 49, comprising a plurality of common housings each corresponding to a respective different one of said plurality of channels, each said common housing containing both the distributed mode loudspeaker and the pistonic loudspeaker of said corresponding channel.

56. Apparatus according to claim 32, comprising a single housing containing said distributed mode loudspeaker, said pistonic loudspeaker and said amplifier.

57. Apparatus according to claim 47, comprising a single housing containing said distributed mode loudspeakers, said pistonic loudspeakers, and said amplifier.

58. Apparatus according to claim 56, including a display unit and driving circuitry for causing said display unit and said loudspeakers and said amplifier to operate in combination for producing audiovisual material.

59. Apparatus according to claim 57, including a display unit and driving circuitry for causing said display unit and said loudspeakers and said amplifier to operate in combination for producing audiovisual material.

60. Apparatus according to claim 32, which comprises part of an electrical musical instrument.

61. Apparatus according to claim 9, wherein said electrical musical instrument is a digital piano.

62. A digital keyboard musical instrument comprising a keyboard, at least one distributed mode loudspeaker, at least one pistonic loudspeaker and electronic circuitry for driving said loudspeakers in response to actuation of the keyboard so that said at least one distributed mode loudspeaker and said at least one pistonic loudspeaker operate simultaneously to produce the same musical notes in response to actuation of the keyboard.

63. A process of generating sound utilizing both a distributed mode loudspeaker device and a pistonic loudspeaker device, each said loudspeaker device being arranged to operate with a frequency response which, measured under anechoic conditions, comprises a substantially flat portion with roll off at each end thereof and in which said substantially flat portions overlap over at least one octave in the frequency band up to 6 kHz, said process comprising driving said distributed mode loudspeaker device and said pistonic loudspeaker device respectively by first and second electrical signals representing substantially the same sound to be reproduced and having frequency ranges which overlap over at least said at least one octave.

64. A loudspeaker assembly which comprises a distributed mode loudspeaker device, a pistonic loudspeaker device, and a circuit having a common input terminal for driving both said loudspeaker devices simultaneously from a common input signal representing the sound to be reproduced, said assembly being such that each said loudspeaker device operates with a frequency response which, measured under anechoic conditions, comprises a substantially flat portion at each end of which there is roll off, said substantially flat portion of said frequency responses overlapping over at least an octave in the frequency band up to 6 kHz.

65. Sound production apparatus comprising:
(a) a distributed mode loudspeaker device,
(b) a pistonic loudspeaker device, and
(c) an amplifier device for driving both said loudspeaker devices, the arrangement being such that
(i) each said loudspeaker device is operable with a frequency response which, measured under anechoic conditions, comprises a substantially flat portion at each end of which there is roll off and in which said substantially flat portions of said frequency responses overlap over at least one octave in the frequency band up to 6 kHz, and
(ii) said amplifier devices may drive said distributed mode loudspeaker devices and said pistonic loudspeaker devices by respective first and second electrical signals representing substantially the same sound to be reproduced and having frequency ranges which overlap over at least said at least one octave.

66. An auxiliary apparatus comprising at least one distributed mode loudspeaker device, and circuitry comprising a high impedance input and an amplifier for amplifying signals derived from the high impedance input and driving the distributed mode loudspeaker device, said auxiliary apparatus being adapted to be connected to a sound reproduction system comprising an amplifier and a pistonic loudspeaker for performing the process of claim 1.

67. A process for modifying an existing sound reproduction system which comprises a signal source, an amplifier and at least one pistonic loudspeaker device, comprising connecting a distributed mode loudspeaker means to said system in order to adapt the system for the performance of a process according to claim 1.

68. A process of modifying an electronic keyboard musical instrument having a keyboard, at least one pistonic loudspeaker and circuitry for driving said at least one pistonic loudspeaker in response to actuation of said keyboard, said process comprising connecting a distributed mode loudspeaker to said circuitry so that said pistonic loudspeaker and said distributed mode loudspeaker are driven so as to produce the same notes in response to actuation of the keyboard.

69. An electrical circuit comprising left and right inputs for connection to the left and right outputs of a stereophonic signal producing device, first and second buffer amplifiers connected to the left and right inputs for buffering the signals applied thereto respectively, each said buffer amplifier having its output connected to a respective pair of further amplifiers, said pairs of amplifiers being operable to provide respectively first and second left channel output signals for driving a left distributed mode loudspeaker and a left pistonic loudspeaker and first and second right channel output signals for respectively driving a right channel distributed mode loudspeaker and a right channel pistonic loudspeaker.

70. Auxiliary apparatus for connection to a digital piano comprising an input for receiving signals from the digital piano representing actuation of the keyboard and pedals, an audio signal generator comprising a digital library of piano sounds and means for selecting signals from said library in accordance with the input signal, an amplifier for amplifying signals derived by selection from the library, and a distributed mode loudspeaker device adapted to be driven by the signals generated by the amplifier.

71. A process of enhancing the spaciousness of sounds produced, in a listening space defined by a boundary, by at least one loudspeaker driven by a signal representing the sound to be reproduced, which comprises driving at least one further loudspeaker by said signal so as to produce a combined sound field in which the value of at least one parameter differs from the value thereof in a field produced by said at least one loudspeaker alone, said difference in value being such as to enhance the spaciousness.

72. A process according to claim 71, in which said parameter is the Lateral Early Energy Fraction and said difference is an increase in the value thereof.

73. A process according to claim 71, in which said parameter is the Inter-Aural Cross Correlation Coefficient and said difference is an increase in the value thereof.

74. A process of enhancing the spaciousness of sounds produced, in a listening space defined by a boundary, by at least one loudspeaker driven by a signal representing the sound to be reproduced, said process comprising driving at least one further loudspeaker by said signal so as to produce a combined sound field in which the value of the Lateral Early Energy Fraction is increased and the value of the Inter-Aural Cross Correlation Coefficient is decreased relative to the values thereof in a sound field produced by said at least one loudspeaker alone.
